(19) United States
(12) Patent Application Publication
(10) Pub. No.: US 2026/0173948 A1
(43) Pub. Date: Jun. 18, 2026

(54) SEMICONDUCTOR PACKAGE AND METHOD OF FORMING THE SAME

(71) Applicant: Taiwan Semiconductor Manufacturing Co., Ltd., Hsinchu (TW)

(72) Inventors: Kuo-Chiang Ting, Hsinchu (TW); Sung-Feng Yeh, Taipei (TW); Ta Hao Sung, Hsinchu (TW); Jia-Kuen Wang, Hsinchu (TW); Li-Cheng Hu, Hsinchu (TW); Ling Fang, Hsinchu (TW)

(21) Appl. No.: 19/197,475

(22) Filed: May 2, 2025

Related U.S. Application Data
(60) Provisional application No. 63/735,723, filed on Dec. 18, 2024.

(51) Int. Cl. H01L 21/56; H01L 23/00; H01L 23/34

(52) U.S. Cl. CPC H10W 74/01; H10W 40/00; H10W 80/211; H10W 80/312; H10W 80/327; H10W 90/792

(57) ABSTRACT

During a bonding process for forming a semiconductor package, an ultra-thin bonding layer (e.g., with a thickness between 5 angstroms and 2500 angstroms) is used at the bonding interface to replace one or both of the bonding layers used at the bonding interface in semiconductor packages without the presently disclosed structures. A plasma process may be performed to activate one of the bonding surfaces, and an intermediate compound layer is formed at the bonding interface by chemical reaction between the materials of the bonding surfaces, in some examples. The intermediate compound layer provides enhanced adhesion for the ultra-thin bonding layer. The enhanced adhesion, ultra-thin thickness, and superior planarity of the ultra-thin bonding layer greatly improves the efficiency of heat dissipation in the semiconductor package formed. Additional advantages include reduced height of the semiconductor package, and the ability to use less expensive material for certain components of the semiconductor package.

### PRIORITY CLAIM AND CROSS-REFERENCE

This application claims priority to U.S. Provisional Patent Application No. 63/735,723, filed Dec. 18, 2024, entitled “Thermal Dissipation Scheme,” which application is hereby incorporated by reference.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

As the demand for shrinking electronic devices has grown, a need for smaller and more creative packaging techniques of semiconductor dies has emerged. An example is the System on Integrated Chips (SoIC) technology, which is a three-dimensional (3D) inter-chip stacking technology that integrates active and/or passive chips into a single System on Chip (SoC) system. The SoIC platform uses front-end technologies and precision methodologies from silicon fabrication plants to stack chips in 3D. The SoIC platform allows for the integration of Known-good-dies (KGDs) with different chip sizes, functionalities, and wafer node technologies. The resulting structure enables ultra-high-density vertical stacking to achieve high performance, low power, and low resistance-inductance-capacitance (RLC). These packaging technologies enable production of semiconductor devices with enhanced functionalities and small footprints.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-3 illustrate cross-sectional views of a semiconductor device at various stages of manufacturing, in accordance with an embodiment.

FIG. 4 illustrates a cross-sectional view of a semiconductor device, in accordance with an embodiment.

FIGS. 5-11 illustrate cross-sectional views of a semiconductor structure at various stages of manufacturing, in accordance with an embodiment.

FIGS. 12-14 illustrate cross-sectional views of a semiconductor structure at various stages of manufacturing, in accordance with another embodiment.

FIG. 15 illustrates a cross-sectional view of a semiconductor structure, in accordance with another embodiment.

FIG. 16 illustrates a cross-sectional view of a semiconductor structure, in accordance with another embodiment.

FIG. 17 illustrates a cross-sectional view of a semiconductor structure, in accordance with another embodiment.

FIG. 18 illustrates a cross-sectional view of a semiconductor structure, in accordance with another embodiment.

FIG. 19 illustrates a cross-sectional view of a semiconductor structure, in accordance with another embodiment.

FIG. 20 illustrates a cross-sectional view of a semiconductor structure, in accordance with another embodiment.

FIG. 21 illustrates a cross-sectional view of a semiconductor structure, in accordance with another embodiment.

FIG. 22 illustrates a cross-sectional view of a semiconductor structure, in accordance with another embodiment.

FIG. 23 illustrates a cross-sectional view of a semiconductor structure, in accordance with another embodiment.

FIG. 24 illustrates a cross-sectional view of a semiconductor structure, in accordance with yet another embodiment.

FIG. 25 illustrates a flow chart of a method of forming a semiconductor structure, in an embodiment.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. Throughout the description, unless otherwise specified, the same or similar reference numerals in different figures refer to the same or similar component formed by a same or similar method using a same or similar material(s).

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclose are discussed in the context of forming SoIC packages, with the understanding that the disclosed bonding schemes, structures, and methods may be applied to other types of semiconductor structures, such as integrated fan-out (InFO) packages, integrated fan-out package-on-package (InFO_PoP) structures, or the like.

In some embodiments, during a bonding process for forming a semiconductor package, an ultra-thin bonding layer (e.g., with a thickness between 5 angstroms and 2500 angstroms) is used at the bonding interface to replace one or both of the bonding layers used at the bonding interface in semiconductor packages without the presently disclosed structures. A plasma process may be performed to activate one of the bonding surfaces, and an intermediate compound layer is formed at the bonding interface by chemical reaction between the materials of the bonding surfaces, in some embodiments. The intermediate compound layer provides enhanced adhesion for the ultra-thin bonding layer. The enhanced adhesion, ultra-thin thickness, and superior planarity of the ultra-thin bonding layer greatly improves the efficiency of heat dissipation in the semiconductor package formed. Additional advantages include reduced height of the semiconductor package formed, and the ability to use less expensive material (e.g., silicon) for certain components (e.g., heat sink) of the semiconductor package.

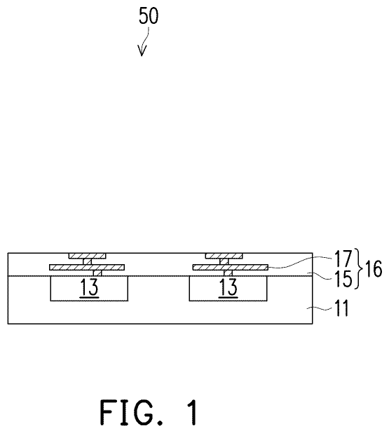

FIGS. 1-3 illustrate cross-sectional views of a semiconductor device 50 at various stages of manufacturing, in accordance with an embodiment. In some embodiments, the semiconductor device 50 is a semiconductor die (may also be referred to as a die). The semiconductor device 50 is used as a top die in the formation of a System on Integrated Chips (SoIC) package in the illustrated embodiments. Details are discussed hereinafter.

In FIG. 1, device regions 13 are formed in a semiconductor substrate 11 (also referred to as a substrate 11). The device regions 13 comprise active electrical components (e.g., transistors, diodes) or passive electrical components (e.g., resistors, capacitors, inductors) formed in or on the substrate 11. The electrical components in the device regions 13 are interconnected by the subsequently formed interconnect structure 16 to form functional circuits of the semiconductor die 50.

The substrate 11 may be a semiconductor substrate (e.g., a silicon substrate), doped or undoped, or an active layer of a semiconductor-on-insulator (SOI) substrate. The semiconductor substrate may include other semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

The electrical components in the device regions 13 comprise a wide variety of active components (e.g., transistors, diodes) and/or passive devices (e.g., capacitors, resistors, inductors), and the like. The electrical components may be formed either within or on the substrate 11 using any suitable methods.

The interconnect structure 16 is formed over the substrate 11 and the device regions 13. The interconnect structure 16 may include an Inter-Layer Dielectric (ILD, not labeled separately) filling the spaces between the gate stacks of transistors (not shown) in the device regions 13. In accordance with some embodiments, the ILD is formed of silicon oxide, Phospho Silicate Glass (PSG), Boro Silicate Glass (BSG), Boron-doped Phospho Silicate Glass (BPSG), Fluorine-doped Silicate Glass (FSG), or the like. The ILD may be formed using spin-on coating, Flowable Chemical Vapor Deposition (FCVD), or the like. In accordance with some embodiments of the present disclosure, the ILD may also be formed using a deposition method such as Plasma Enhanced Chemical Vapor Deposition (PECVD), Low Pressure Chemical Vapor Deposition (LPCVD), or the like.

Contact plugs are formed in the ILD, and are used to electrically connect the device regions 13 to overlying metal lines and vias. In accordance with some embodiments of the present disclosure, the contact plugs are formed of or comprise a conductive material selected from tungsten, aluminum, copper, titanium, tantalum, titanium nitride, tantalum nitride, alloys therefore, and/or multi-layers thereof. The formation of the contact plugs may include forming contact openings in the ILD, filling a conductive material(s) into the contact openings, and performing a planarization process (such as a Chemical Mechanical Polish (CMP) process or a mechanical grinding process) to level the top surfaces of the contact plugs with the top surface of the ILD. In the discussion herein, unless otherwise specified, the terms “conductive” and “conductive material” are used to refer to “electrically conductive” and “electrically conductive material,” respectively.

In accordance with some embodiments, the interconnect structure 16 further includes a plurality of dielectric layers 15 and a plurality of conductive features 17, such as metal lines and vias, in the dielectric layers 15. The dielectric layers 15 (also referred to as Inter-Metal Dielectrics (IMDs)) may include low-k dielectric layers in accordance with some embodiments. The dielectric constants (k values) of the low-k dielectric layers may be lower than about 3.5 or 3.0, for example. The low-k dielectric layers may comprise a carbon-containing low-k dielectric material, Hydrogen SilsesQuioxane (HSQ), MethylSilsesQuioxane (MSQ), or the like.

The formation of metal lines and vias in the dielectric layers 15 may include single damascene processes and/or dual damascene processes. In a single damascene process for forming a metal line or a via, a trench or a via opening is first formed in one of the dielectric layers 15, followed by filling the trench or the via opening with a conductive material(s). A planarization process such as a CMP process is then performed to remove the excess portions of the conductive material higher than the top surface of the dielectric layer, leaving a metal line or a via in the corresponding trench or via opening. In a dual damascene process, both of a trench and a via opening are formed in a dielectric layer, with the via opening underlying and connected to the trench. A conductive material(s) is then filled into the trench and the via opening to form a metal line and a via, respectively. The conductive material may include a diffusion barrier layer and a copper-containing metallic material over the diffusion barrier layer. The diffusion barrier layer may include titanium, titanium nitride, tantalum, tantalum nitride, or the like.

Metal lines of the interconnect structure 16 include top conductive features such as metal lines or metal pads in a top dielectric layer (e.g., distal from the substrate 11) of the interconnect structure 16. In accordance with some embodiments, the top dielectric layer is formed of a low-k dielectric material similar to the material of lower ones of the dielectric layers 15. In other embodiments, the top dielectric layer is formed of a non-low-k dielectric material such as silicon oxide, silicon nitride, undoped silicate glass, or the like. The top conductive features in the top dielectric layer may also be formed of copper or a copper alloy, and may have a dual damascene structure or a single damascene structure.

In some embodiments, multiple semiconductor dies 50 are formed on the substrate 11 (e.g., a wafer). A probing process may be performed to test the semiconductor dies 50, and to identify the semiconductor dies 50 with defect. The probing process may be performed through the top conductive features of the interconnect structure 16.

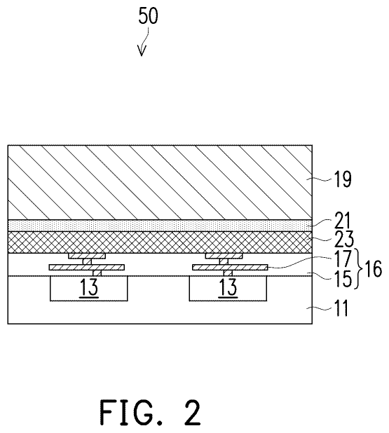

Next, in FIG. 2, a bonding layer 23 is formed on the interconnect structure 16, and a bonding layer 21 (may also be referred to as an ultra-thin bonding layer 21) is formed on a support substrate 19. The support substrate 19 is a pre-formed substrate (e.g., formed prior to the bonding and the formation of the bonding layer 21), such as a silicon substrate. Next, the bonding layer 21 is bonded to the bonding layer 23, such that the support substrate 19 is attached to the substrate 11. In some embodiments, the bonding between the bonding layers 23 and 21 is achieved through dielectric-to-dielectric bonding (e.g., without using an adhesive layer). More details of dielectric-to-dielectric bonding are discussed hereinafter.

In some embodiments, the bonding layer 23 is formed of a suitable dielectric material, such as aluminum oxide, silicon oxide, silicon carbonitride, titanium oxide, aluminum nitride, boron nitride, silicon oxynitride, or silicon oxycarbide, using a suitable formation method such as chemical vapor deposition (CVD), atomic layer deposition (ALD), or the like. A thickness of the bonding layer 23 may be between about 5 angstroms and about 2500 angstroms. A thermal conductivity of the bonding layer 23 may be between about 0.5 watts per meter per Kelvin (W/(m·K)) and about 20 W/(m·K). In some embodiments, the bonding layer 21 is formed of a suitable dielectric material, such as aluminum oxide, silicon oxide, silicon carbonitride, titanium oxide, aluminum nitride, boron nitride, silicon oxynitride, or silicon oxycarbide, using a suitable formation method such as CVD, ALD, or the like. A thickness of the bonding layer 21 may be between about 5 angstroms and about 2500 angstroms. In some embodiments, the thickness of the bonding layer 23 is between about 10 times and 100 times of the thickness of the bonding layer 21. A thermal conductivity of the bonding layer 21 may be between about 0.5 W/(m·K) and about 20 W/(m·K). The bonding layers 21 and 23 are formed of a same dielectric material, in some embodiments. In other embodiments, the bonding layers 21 and 23 are formed of different dielectric materials.

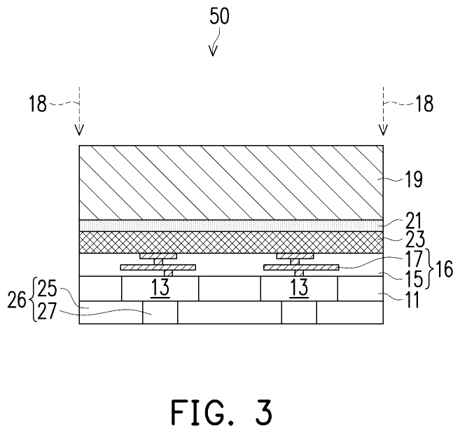

Next, in FIG. 3, a thinning process is performed from the backside of the substrate 11 to reduce the thickness of the substrate 11. The thinning process may be a mechanical grinding process, a chemical mechanical planarization (CMP) process, an etch back process, combinations thereof, or the like. After the thinning process, a backside interconnect structure 26 is formed at the backside of the substrate 11. The backside interconnect structure 26 includes one or more dielectric layers 25 and conductive features 27 (e.g., metal lines, vias, bond pads) formed in the one or more dielectric layers 25, in some embodiments. The conductive features 27 of the backside interconnect structure 26 are electrically coupled to the electrical components in the device regions 13. The materials and formation method of the backside interconnect structure 26 may be the same as or similar to those of the interconnect structure 16, thus not repeated. Note that for simplicity, one dielectric layer 25 and one layer of conductive features 27 are illustrated for the backside interconnect structure 26 in FIG. 3, with the understanding that the number of dielectric layers 25 and the number of layers of conductive features 27 in the backside interconnect structure 26 (or the interconnect structure 16) may be any suitable number.

Next, a singulation process (also referred to as a dicing process) is performed along dicing regions indicated by the dashed lines 18 in FIG. 3 to separate the plurality of semiconductor dies 50 formed on the substrate 11 into individual (e.g., separate) semiconductor dies 50. Known-good-dies (KGD) of the semiconductor dies 50 are used in subsequent processing steps to form the SoIC package. Note that in the example of FIG. 3, each of the semiconductor dies 50 includes (a portion of) the support substrate 19 (e.g., a bulk silicon material) bonded to the substrate 11 through the bonding layers 21 and 23. The support substrate 19 in the semiconductor die 50 functions as a built-in heat dissipator (also referred to as a built-in heat sink) of the semiconductor die 50, which facilitates heat dissipation away from the semiconductor die 50 in the SoIC package formed subsequently, in some embodiments. In addition, the thermal conductivity of the bonding layers 21 and 23 of the semiconductor die 50, togther with their small thicknesses, also facilitate heat dissipation away from the semiconductor die 50.

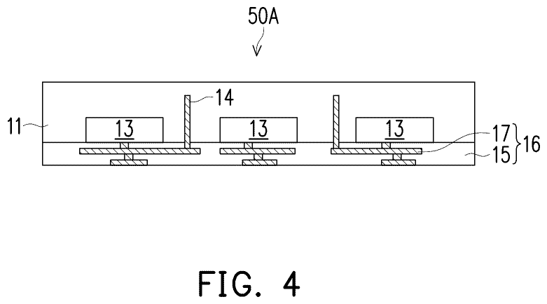

FIG. 4 illustrates a cross-sectional view of a semiconductor device 50A, in accordance with an embodiment. In the illustrated embodiments, the semiconductor device 50A is a semiconductor die similar to the semiconductor die 50, but with through substrate vias (TSVs) 14 and without the support substrate 19 and the bonding layers 21 and 23. The semiconductor device 50A may be formed using the same or similar formation method as the semiconductor device 50, as skilled artisans readily appreciate, thus details may not be repeated. A probing process is performed to test the semiconductor dies 50A, and the the semiconductor dies 50A that pass the test (e.g., the KGDs) are used in forming the SoIC package in subsequent processing.

In the example of FIG. 4, the TSVs 14 are electrically coupled to conductive features 17 of the interconnect structure 16 of the semiconductor device 50A. In the illustrated embodiments, the TSVs 14 extend from the front side of the substrate 11 (or from a location inside the interconnect structure 16) to an intermediate level of the substrate 11. The intermediate level of substrate 11 is between the front side and the backside of the substrate 11. In some embodiments, each of the TSVs 14 is encircled by a dielectric isolation layer (e.g., a diffusion barrier layer, not shown), which is used for electrically insulating the sidewalls of the corresponding TSV 14 from the substrate 11.

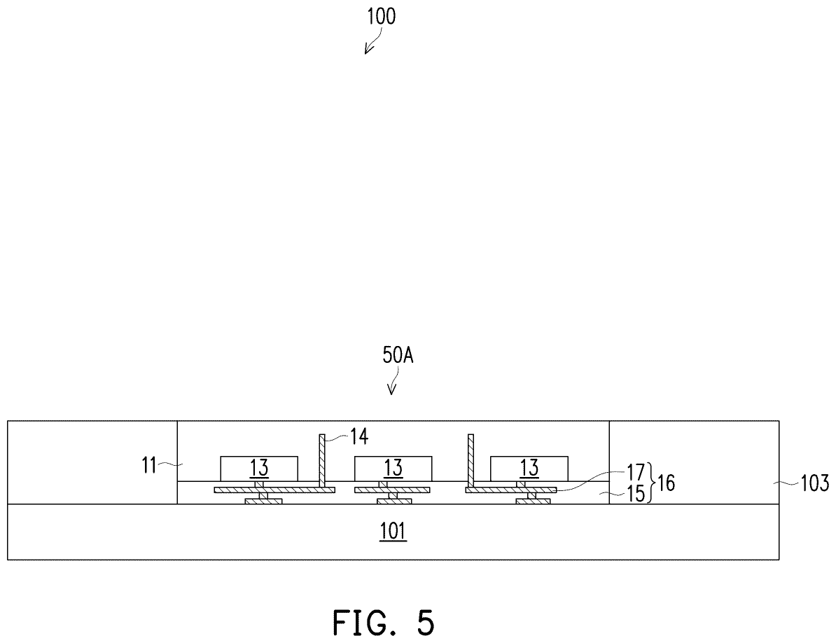

FIGS. 5-11 illustrate cross-sectional views of a semiconductor structure 100 at various stages of manufacturing, in accordance with an embodiment. The semiconductor structure 100 is an SoIC package in the illustrated embodiments, and therefore, may also be referred to as a semiconductor package 100, or an SoIC package 100. In the illustrated embodiments, the semiconductor dies 50A and 50 are used as the bottom die and the top die of the SoIC package, respectively.

Referring to FIG. 5, the front sides of the semiconductor dies 50A are attached to a carrier 101 (also referred to as a carrier substrate). It is appreciated that although one semiconductor die 50A is illustrated, there are a plurality of semiconductor dies 50A attached to the carrier 101, and the plurality of semiconductor dies 50A may be arranged as an array. In some embodiments, the processing steps of FIGS. 5-11 form multiple semiconductor packages 100 in a wafer structure, and a subsequent singulation process is performed to separate the multiple semiconductor packages 100 into individual (e.g., separate) semiconductor packages 100. For simplicity, FIGS. 5-11 illustrate the cross-sectional views corresponding to one of the semiconductor packages 100 formed in the wafer structure.

In accordance with some embodiments, the carrier 101 is a semiconductor carrier such as a silicon carrier, and the semiconductor dies 50A is attached to the carrier 101 using an adhesive layer, such as a die-attaching film (DAF). In some embodiments, a first dielectric layer (not illustrated), such as silicon oxide, silicon carbide, silicon nitride, or the like, is formed on the upper surface of the carrier 101, and a second dielectric layer (not illustrated) same as or similar to the first dielectric layer is formed on an exterior surface of the interconnect structure 16 (e.g., distal from the substrate 11) of each of the semiconductor dies 50A. The semiconductor dies 50A are then attached to the carrier 101 by a dielectric-to-dielectric bonding between the first dielectric layer and the second dielectric layer. In some embodiments, the carrier 101 is a transparent substrate such as a glass substrate, and an adhesive layer, such as a light-to-heat-conversion (LTHC) material, is formed on the upper surface of the carrier 101 for attaching the semiconductor dies 50A.

Next, as shown in FIG. 5, a gap-filling process is performed to fill the gaps between neighboring semiconductor dies 50A, and to encapsulate the semiconductor dies 50A in a gap-fill layer 103 (also referred to as an encapsulant). In accordance with some embodiments, the gap-fill layer 103 comprises a dielectric liner, and a dielectric gap-fill material over the dielectric liner. The dielectric liner and the dielectric gap-fill material are not shown separately. The dielectric liner may be formed of a material that has good adhesion to the semiconductor dies 50A. In accordance with some embodiments, the dielectric liner is formed of or comprises silicon nitride. The dielectric liner is formed in a conformal deposition process, and hence is a conformal layer. The dielectric gap-fill material may be formed of an oxide-base dielectric material, such as silicon oxide, silicon oxynitride, a silicate glass, or the like. The dielectric liner and the dielectric gap-fill material may be formed through deposition processes such as CVD, ALD, combinations thereof, or the like.

In accordance with alternative embodiments, the gap-fill layer 103 is formed of or comprises a molding material, such as a molding compound, a molding underfill, or the like. The corresponding process may include dispensing a dielectric material in a flowable form, and curing the dielectric material. Next, after the gap-fill layer 103 is deposited, a planarization process, such as CMP, is performed to level the top surfaces of semiconductor dies 50A with the top surface of the gap-fill layer 103.

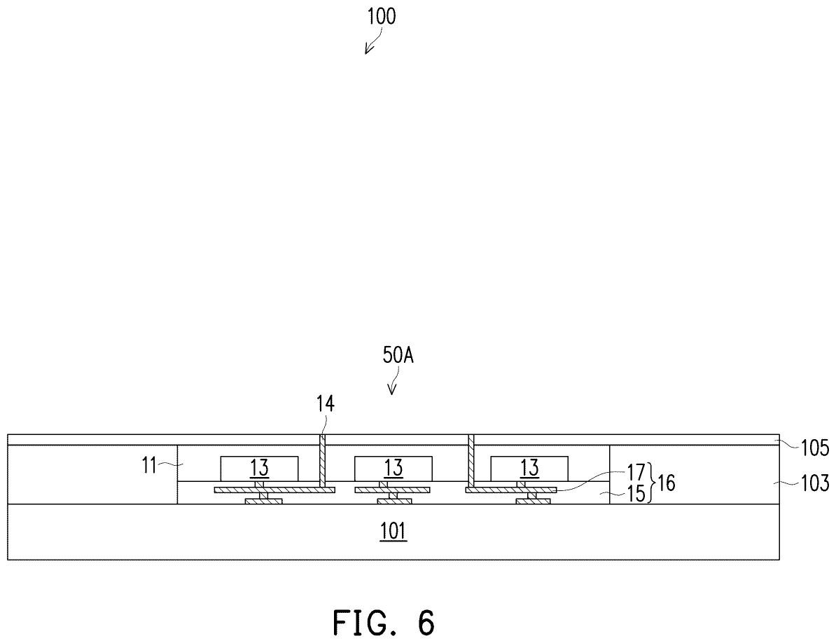

Next, in FIG. 6, the substrates 11 of the semiconductor dies 50A and the gap-fill layer 103 are recessed to expose the upper portions of the TSVs 14. In some embodiments, one or more etching processes are performed using an etchant(s) that is selective to (e.g., having a higher etching rate for) the materials of the substrate 11 and the gap-fill layer 103 to recesses the substrate 11 and the gap-fill layer 103. The TSVs 14 are substantially un-etched by the one or more etching processes, thus protrude above the (recessed) substrates 11. The remaining portions of the gap-fill layer 103 after the one or more etching processes are referred to as gap-fill regions 103 hereinafter.

Next, a dielectric isolation layer 105 is formed over the semiconductor dies 50A, over the gap-fill regions 103, and around the TSVs 14. The dielectric isolation layer 105 may be formed of a suitable dielectric material, such as silicon oxide, silicon nitride, a low-k dielectric material, or the like, using a suitable formation method such as CVD, ALD, or the like. Next, a planarization process, such as CMP, is performed to achieve a level upper surface between the TSVs 14 and the dielectric isolation layer 105. In other words, after the planarization process, the dielectric isolation layer 105 covers (e.g., contacts and extends along) sidewalls of the TSVs 14, and exposes the upper surfaces of the TSVs 14. The dielectric isolation layer 105 after the planarization process is considered part of the semiconductor die 50A, in some embodiments.

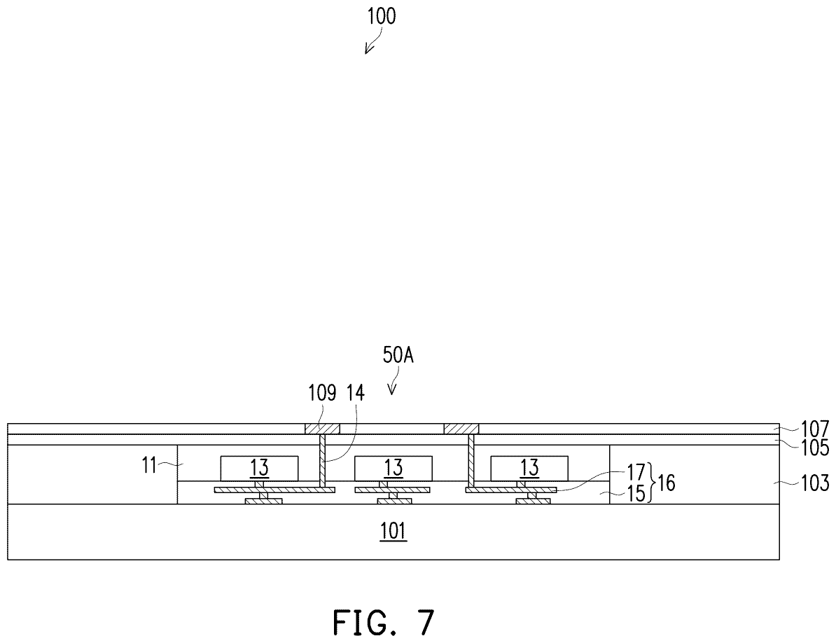

Referring next to FIG. 7, a bonding layer 107 is deposited over the dielectric isolation layer 105, and bond pads 109 (may also be referred to as contact pads) are formed in the bonding layer 107. The bonding layer 107 may be formed of a silicon-containing dielectric material, such as silicon oxide, silicon carbide, silicon nitride, silicon oxynitride, silicon oxycarbide, silicon carbonitride, silicon oxycarbonitride, the like, or combinations thereof, using a suitable formation method such as CVD, ALD, combinations thereof, or the like. A planarization process may be performed next to achieve a level upper surface for the bonding layer 107.

The bond pads 109 are formed in the bonding layer 107. In accordance with some embodiments, the bond pads 109 are formed by etching the bonding layer 107 to form openings in the bonding layers 107 that expose the upper surfaces of the TSVs 14, filling the openings with a conductive material(s), and performing a planarization process such as a CMP. The top surfaces of the bond pads 109 and the bonding layer 107 are thus coplanar with each other. The bond pads 109 may include a conductive material such as copper, titanium, titanium nitride, tantalum, tantalum nitride, combinations thereof, or the like. For example, each bond pad 109 may include a titanium nitride barrier layer, and a copper region on the titanium nitride barrier layer. The bonding layer 107 and the bond pads 109 are considered as parts of the semiconductor die 50A, in some embodiments.

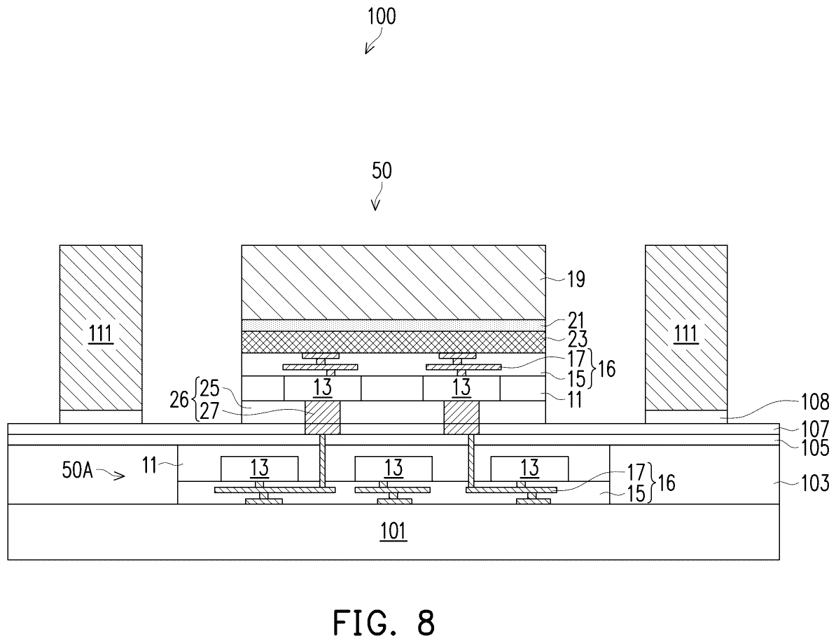

Referring next to FIG. 8, the semiconductor dies 50 are bonded to the semiconductor dies 50A. Although one semiconductor die 50 is illustrated, the illustrate semiconductor die 50 represents a plurality of semiconductor dies 50, each over and bonded to a respective underlying semiconductor die 50A. The bonding may be performed through a face-to-back bonding process, with the front sides of the semiconductor dies 50 bonded to the backsides of the semiconductor dies 50A.

In the illustrated embodiments, the bond pads 109 of the semiconductor dies 50A are bonded to respective bond pads of the conductive features 27 of the semiconductor dies 50 through metal-to-metal bonding. In addition, the bonding layer 107 of the semiconductor die 50A is bonded to the topmost dielectric layer 25 of the backside interconnect structure 26 of the semiconductor die 50 through dielectric-to-dielectric bonding. The structure illustrated in FIG. 8 is a wafer structure comprising multiple semiconductor packages 100, and may be referred to as a reconstructed wafer 100 before the subsequent singulation process, and more features will be formed to further expand the reconstructed wafer 100 in subsequent processing steps.

Dielectric-to-dielectric bonding (also referred to as direct dielectric-to-dielectric bonding) and metal-to-metal bonding (also referred to as direct metal-to-metal bonding) are bonding techniques that could be used in a direct bonding process to bond two semiconductor devices together without using an intermediate layer (e.g., solder or an adhesive layer). The direct bonding process uses dielectric-to-dielectric bonding and/or metal-to-metal bonding to achieve a robust and reliable connection at the interface of two devices. Metal-to-metal bonding involves aligning and applying sufficient pressure on metal surfaces, such as copper or aluminum surfaces, often accompanied by thermal treatment to facilitate atomic diffusion and interfacial adhesion without an intermediate layer (e.g., solder). Dielectric-to-dielectric bonding uses surfaces such as silicon dioxide or other insulating materials, which, when aligned under appropriate conditions (e.g., at an elevated temperature and/or with pressure applied at the surfaces), form bonds through forces such as Van der Waals force. The direct bonding process is instrumental in creating high-density, low-resistance connections while reducing or minimizing thermal budgets.

Still referring to FIG. 8, a plurality of dummy dies 111 are also attached to the bonding layer 107. In accordance with some embodiments, each of the dummy dies 111 is attached through a layer 108. The layer 108 may be a bonding layer that is a silicon-containing dielectric material, such as silicon oxide, silicon carbide, silicon nitride, silicon oxynitride, silicon oxycarbide, silicon carbonitride, silicon oxycarbonitride, combinations thereof, or the like. The dummy dies 111 may be attached by dielectric-to-dielectric bonding between the bonding layer 107 and the layer 108. In accordance with some embodiments, a same anneal process may be performed to facilitate the direct bonding of the dummy dies 111 and the semiconductor dies 50 to the underlying structure.

In accordance with alternative embodiments, the dummy dies 111 are attached to the bonding layer 107 through an adhesive layer (e.g., a DAF). In other words, the layer 108 may be a DAF.

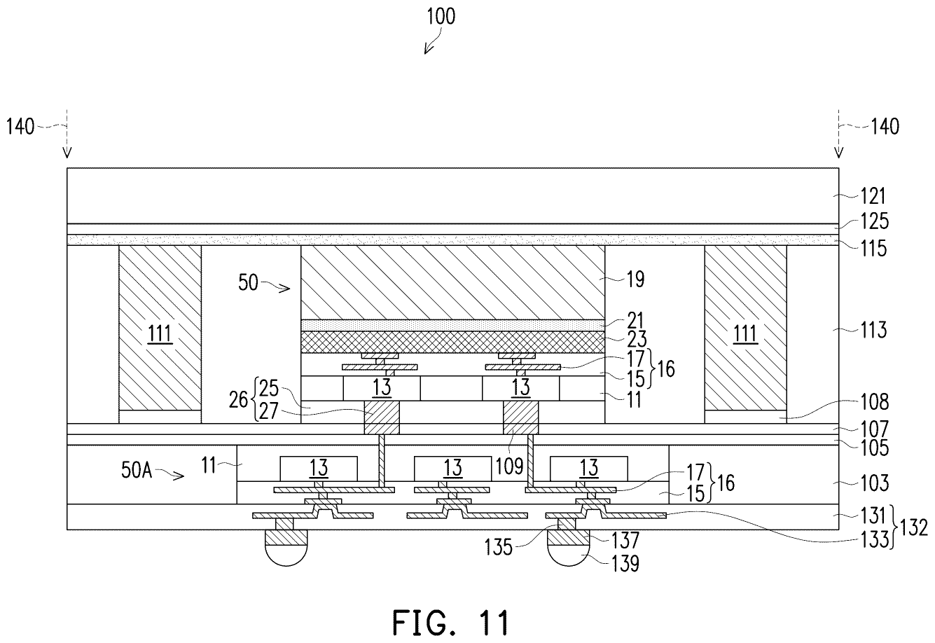

The dummy dies 111 provide structural support to, thus improving the structural integrity of, the SoIC package 100 formed. In addition, the dummy dies 111 also function as heat dissipation paths between the semiconductor die 50A and the heat sink (see, e.g., 121 in FIG. 11) formed subsequently.

In accordance with some embodiments, the entire dummy die 111 is formed of a homogeneous material, with no other materials and structures therein. For example, the dummy die 111 may be formed of a semiconductor material, such as silicon (e.g., a bulk silicon material), which has a thermal conductivity of about 150 W/(m·K). The dummy die 111 may alternatively be formed of a material having a higher thermal conductivity than silicon. For example, the dummy die 111 may be formed of a suitable dielectric material or a suitable conductive material (such as a metal). For instance, the dummy die 111 may be formed of SiC (with a thermal conductivity of about 160 W/(m·K)), AlN (with a thermal conductivity of about 180 W/(m·K)), Ag (with a thermal conductivity of about 429 W/(m·K)), or the like, while other materials such as Al, BeO, Cu, Au, SiCN, or the like, may also be used. As will be discussed in more details hereinafter, the disclosed SoIC package 100 achieves low thermal resistance (or equivalently, high heat dissipation efficiency) between the semiconductor dies 50/50A and the heat sink (see, e.g., 121 in FIG. 11), which lower thermal resistance was not achievable by previous designs. As a result, the dummy die 111 in the disclosed SoIC package may be formed of silicon instead of other material having a higher thermal conductivity, while still achieving satisfactory thermal dissipation for the SoIC package formed. Note that dummy dies 111 formed of silicon may be much less expensive and less time-consuming to make than dummy dies 111 formed of other materials such as those listed above.

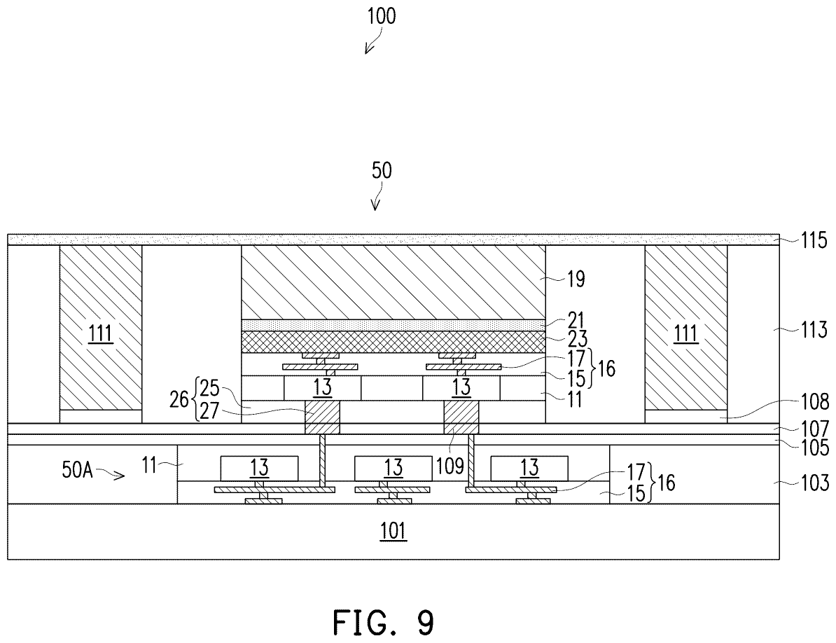

Next, referring to FIG. 9, gap-fill regions 113 (also referred to as an encapsulant) are formed. The formation process, the structure, and the material of the gap-fill regions 113 may be the same as or similar to those of the gap-fill regions 103. For example, the gap-fill regions 113 may include a dielectric liner, and a dielectric gap-fill layer over the dielectric liner. Alternatively, the gap-fill regions 113 may comprise a molding compound, a molding underfill, or the like. A planarization process is performed to level the top surfaces of the support substrates 19 of the semiconductor dies 50, the dummy dies 111, and the gap-fill regions 113.

Next, a bonding layer 115 (also referred to as a bonding film) is deposited on the support substrates 19 of the semiconductor dies 50, the dummy dies 111, and the gap-fill regions 113. A planarization process may then be performed to level the top surface of the bonding layer 115. In some embodiments, the planarization process is omitted, due to the as-deposited bonding layer 115 already having good planarity (e.g., being formed by an ALD process). In some embodiment, the bonding layer 115 is formed of a suitable dielectric material such as aluminum oxide (e.g., AlOₓ), silicon oxide (e.g., SiOₓ), silicon carbonitride (e.g., SiCN), titanium oxide (e.g., TiO₂), aluminum nitride (e.g., AlN), boron nitride (e.g., BN), silicon oxynitride (e.g., SiON), or silicon oxycarbide (e.g., SiOC), using a suitable formation method such as CVD, ALD, or the like. A thickness of the bonding layer 115 may be between about 5 angstroms and about 2500 angstroms. A thermal conductivity of the bonding layer 115 may be between about 0.5 W/(m·K) and about 20 W/(m·K). The bonding layer 115 is formed of a same material as the bonding layer 21 of the semiconductor dies 50, in some embodiments.

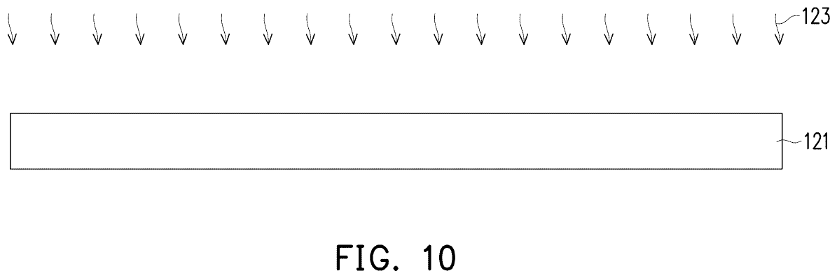

Next, as illustrated in FIG. 10, a plasma process 123 is performed to treat (e.g., activate) a surface of a heat sink 121, in preparation for bonding of the heat sink 121 to the bonding layer 115. The heat sink 121 is pre-formed before the plasma process 123, in the illustrated embodiments.

In accordance with some embodiments, the entire heat sink 121 is formed of a homogeneous material, with no other materials and structures therein. For example, the heat sink 121 may be formed of a semiconductor material, such as silicon (e.g., a bulk silicon material, such as a silicon wafer). The heat sink 121 may alternatively be formed of a suitable dielectric material or an electrically conductive material, such as the materials listed above for the dummy dies 111. In an example embodiment, the heat sink 121 and the dummy dies 111 are formed of silicon. Due to the excellent heat dissipation capability achieved by the disclosed SoIC package, the dummy dies 111 and the heat sink 121 in the disclosed SoIC package may be formed of silicon instead of other materials having higher thermal conductivities, while still achieving satisfactory thermal dissipation for the SoIC package formed. Note that heat sink 121 formed of silicon may be much less expensive and less time-consuming to make than heat sinks formed of other materials such as those listed above for the dummy dies 111.

In some embodiments, the plasma process is performed by igniting a gas source into a plasma, then treating the surface of the heat sink 121 (e.g., silicon) with the plasma. The gas source may be an inert gas (e.g., Ar, He, Ne), a reactive gas (e.g., N₂, O₂, H₂, NH₃), or a mixture of an inert gas and a reactive gas (e.g., a mixture of Ar and O₂, a mixture of N₂ and H₂, or a mixture of Ar and N₂). The surface of the heat sink 121 (e.g. silicon) is activated by the plasma process 123. In some embodiments, the plasma bombardment breaks surface bonds and creates dangling bonds on the surface (e.g., silicon surface) of the heat sink 121. In some embodiments, the plasma process 123 creates reactive sites (e.g., free radicals) on the surface (e.g., silicon surface) of the heat sink 121. As a result of the plasma process 123, the treated surface of the heat sink 121 becomes chemically reactive and/or has higher surface energy.

Next, in FIG. 11, the heat sink 121 is bonded to the bonding layer 115, e.g., by pressing the treated surface of the heat sink 121 against (e.g., in direct contact with) the upper surface of the bonding layer 115. In some embodiments, the treated surface of the heat sink 121, which is chemically reactive, forms chemical bonds with the bonding layer 115. As a result, an intermediate compound layer 125 (may also be referred to as an interlayer or an interfacial layer) is formed between the bonding layer 115 and the heat sink 121. In other words, the intermediate compound layer 125 comprises a compound material formed by chemical reaction between the material (e.g., silicon) of the heat sink 121 and the material of the bonding layer 115. As an example, when the bonding layer 115 is formed AlOₓ and the heat sink 121 is formed of silicon (e.g., Si), the compound material of the intermediate compound layer 125 is aluminum silicon oxide (e.g., AlSiO_{y}). As another example, when the bonding layer 115 is formed of TiO₂, AlN, or BN, and the heat sink 121 is formed of Si, the compound material of the intermediate compound layer 125 is TiSiOₓ, AlSiN, or BSiN, respectively. As yet another example, when the bonding layer 115 is formed of a silicon-containing material, such as SiOₓ, SiCN, SiON, or SiCO, and the heat sink 121 is formed of Si, the compound material of the intermediate compound layer 125 is a compound material with different atomic ratio(s) between silicon atoms and other atoms in the compound material, such as SiO_{y}, SiCNₓ, SiONₓ, or SiCOₓ, respectively. In some embodiments, the thickness of the intermediate compound layer 125 is between about 1 angstrom and about 100 angstroms. The thickness of the intermediate compound layer 125 is between about 1/10 and about 1/100 of the thickness of the bonding layer 115, in some embodiments. A thermal conductivity of the intermediate compound layer 125 may be between about 0.5 W/(m·K) and about 20 W/(m·K), as an example.

While the example in FIG. 10 illustrates the plasma process 123 being applied to the heat sink 121, skilled artisans will readily appreciate that the plasma process 123 may alternatively be applied to the upper surface of the bonding layer 115 in FIG. 9, then the heat sink 121 is bonded to the activated surface of the bonding layer 115. The resulting SoIC package has the same or similar intermediate compound layer 125 as illustrated in FIG. 11. These and other modifications are fully intended to be included within the scope of the present disclosure.

For vertically stacked packages such as SoIC packages, more dies are stacked together to increase the integration density of transistors. The higher density of transistors, however, means more heat is generated per unit area. Due to heat accumulation in the package, thermal dissipation becomes a major challenge, which if not addressed properly, may causes performance degradation and/or device failure.

In a reference package without the presently disclosed structures, the bonding between the heat sink 121 and the reconstructed wafer 100 is typically achieved by using two bonding layers. For example, a first bonding layer (e.g., a dielectric layer) is formed at the same location as the bonding layer 115 in FIG. 11, and a second bonding layer (e.g., a dielectric layer) is formed at the lower surface of the heat sink 121. The first bonding layer and the second bonding layer are then bonded together, e.g., through dielectric-to-dielectric bonding. The first bonding layer and the second bonding layer are typically much thicker than the bonding layer 115 in the present disclosure, such as being about 10 times and about 100 times thicker than the bonding layer 115. For example, the first bonding layer and the second bonding layer of the reference package may have thicknesses between about 5,000 angstroms and about 20,000 angstroms. The significantly larger thicknesses of the first bonding layer and the second bonding layer in the reference package drastically reduce the efficiency of heat dissipation between the heat sink 121 and the semiconductor dies 50. In addition, the adhesion between the first bonding layer and the second bonding layer may be much weaker than that achieved in the present disclosure. The weak adhesion may result in void regions (e.g., empty spaces, or tiny air bubbles) between the first bonding layer and the second bonding layer. The void regions further reduce the efficiency of heat dissipation in the reference package.

The disclosed embodiments herein use the ultra-thin bonding layer 115, which has a thickness that is between about 1/10 and about 1/100 of the thickness of the first bonding layer (or the second bonding layer) used in the reference package. This ultra-thin bonding layer 115 achieves much better efficiency of heat dissipation, and reduces the height of the semiconductor structure formed. In addition, the bonding layer 115 achieves enhanced/improved adhesion compared with the reference package, e.g., due to the intermediate compound layer 125 which comprises chemical bonds between the two layers being bonded together. In comparison, the bonding between the first bonding layer and the second bonding layer used in the reference package may include mostly weaker physical bonds achieved through, e.g., Van der Waals force. The enhanced adhesion may prevent or reduce the occurrence of void regions (e.g., tiny air bubbles) between the layers being bonded together, further improving the efficiency of heat dissipation. Furthermore, due to the small thickness of the bonding layer 115, the bonding layer 115 may be formed using formation methods having superior planarity, such as ALD. The improved planarity of the bonding layer 115 further facilitates the bonding with another layer, and may obviate the planarization process used for planarizing the bonding layer 115. Note that formation method such as ALD may not be practical or economical for forming the first bonding layer and the second bonding layer used in the reference package, due to the huge thickness of the first bonding layer (or the second bonding layer) and the time needed to achieve that thickness.

Still referring to FIG. 11, after the heat sink 121 is bonded, the carrier 101 is de-bonded, a redistribution structure (RDS) 132 is formed at the front side of each of the semiconductor dies 50A, and electrical connectors 90 are formed on the RDS 132.

In some embodiments, the carrier 101 is de-bonded by a suitable removal process, such as an etching process, a CMP process, a mechanical grinding process, combinations thereof, or the like. In embodiments where the carrier 101 is a glass carrier and LTHC coating material is used to bond the semiconductor dies 50A, the carrier 101 may be de-bonded by shining a light (e.g., an UV light or a laser beam) through the carrier 101 onto the LTHC coating material, so that the LTHC coating material is decomposed, thus releasing the reconstructed wafer 100 from the carrier 101. In embodiments where an adhesive layer (e.g., DAF) is used to bond the semiconductor dies 50A, the adhesive may also be removed (at least partially) by the carrier de-bonding process. After the carrier de-bonding process, remaining portions of the adhesive layer may be removed by an etching process, and conductive features 17 (e.g., contact pads) of the interconnect structure 16 of the semiconductor dies 50A are exposed.

Next, the RDS 132 is formed on the interconnect structures 16 of the semiconductor die 50A, and is electrically coupled to the exposed conductive features 17 of the interconnect structure 16. The redistribution structure 132 comprises conductive features such as one or more layers of conductive lines 133 and vias 135 formed in one or more dielectric layers 131. In some embodiments, the one or more dielectric layers 131 are formed of a polymer, such as polybenzoxazole (PBO), polyimide, benzocyclobutene (BCB), or the like. In other embodiments, the dielectric layer 131 is formed of a nitride such as silicon nitride; an oxide such as silicon oxide, phosphosilicate glass (PSG), borosilicate glass (BSG), or boron-doped phosphosilicate glass (BPSG); or the like. The one or more dielectric layers 131 may be formed by any acceptable deposition process, such as spin coating, CVD, laminating, the like, or a combination thereof.

In some embodiments, the conductive features of the redistribution structure 132 comprise conductive lines 133 and via 135 formed of a suitable conductive material such as copper, titanium, tungsten, aluminum, or the like. The conductive features may be formed by, e.g., forming openings in the dielectric layer 131 to expose underlying conductive features, forming a seed layer over the dielectric layer 131 and in the openings, forming a patterned photoresist with a designed pattern over the seed layer, plating (e.g., electroplating or electroless plating) the conductive material in the designed pattern and over the seed layer, and removing the photoresist and portions of seed layer on which the conductive material is not formed.

Next, as shown in FIG. 11, connectors 137 (may also be referred to as conductive bumps, external connectors) are formed on the RDS 132, and are electrically coupled to the conductive features of the RDS 132 to provide electrical connection to external circuits. The connectors 137 may be solder balls, metal pillars, controlled collapse chip connection (C4) bumps, micro bumps, electroless nickel-electroless palladium-immersion gold technique (ENEPIG) formed bumps, combination thereof (e.g., a metal pillar having a solder ball attached thereof), or the like. The connectors 137 may include a conductive material such as solder, copper, aluminum, gold, nickel, silver, palladium, tin, the like, or a combination thereof. In some embodiments, the connectors 137 comprise metal pillars (such as a copper pillar) formed by a sputtering, printing, electro plating, electroless plating, CVD, or the like, with or without a solder material 139 thereon. The metal pillars may be solder free and have substantially vertical sidewalls or tapered sidewalls.

In some embodiments, multiple SoIC packages are formed in the reconstructed wafer 100. A singulation process (also referred to as dicing process) is performed along dicing regions indicated by the dashed lines 140 in FIG. 11. After the singulation process, multiple individual (e.g., separate) SoIC packages 100 are formed. FIG. 11 illustrates one of the SoIC packages 100.

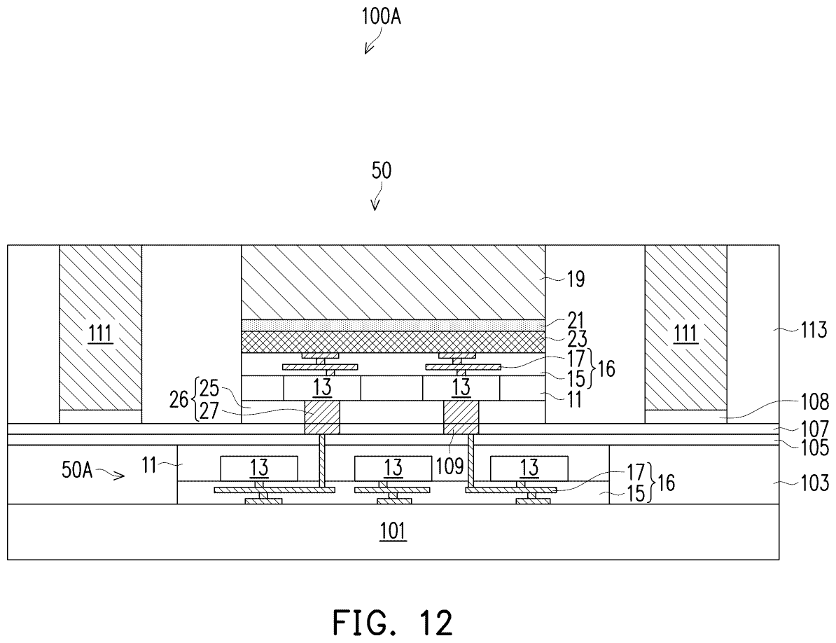

FIGS. 12-14 illustrate cross-sectional views of a semiconductor structure 100A at various stages of manufacturing, in accordance with another embodiment. The structure of FIG. 12 may be formed by performing the same or similar processing steps for forming the structure in FIG. 9, but without forming the bonding layer 115. The structure of FIG. 12 may also be referred to as a reconstructed wafer 100A before the subsequent singulation process.

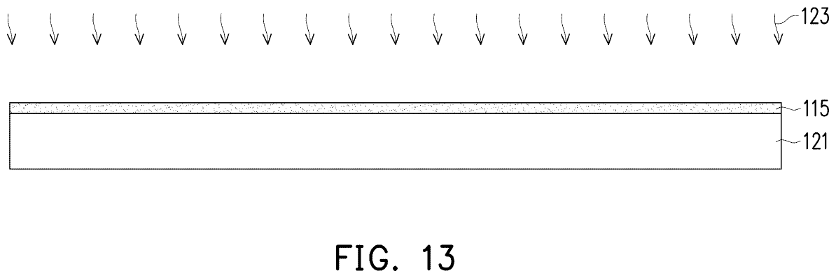

Next, in FIG. 13, the bonding layer 115 is formed on the heat sink 121 (e.g., a bulk silicon material, a silicon wafer). The material and the formation method for the bonding layer 115 are the same as or similar to those discussed above, thus not repeated. Next, the plasma process 123 is performed to treat (e.g., activate) the surface of the bonding layer 115, details are the same as or similar to those discussed above, thus not repeated.

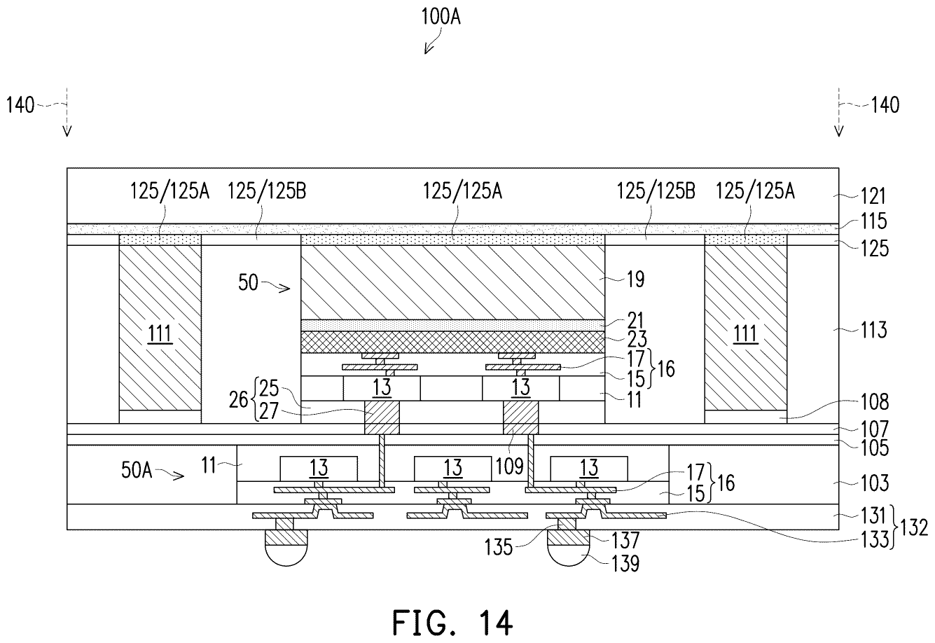

Next, in FIG. 14, the treated (e.g., activated) surface of the bonding layer 115 are bonded to the reconstructed wafer 100A. For example, the bonding layer 115 is bonded to the semiconductor dies 50, the dummy dies 111, and the gap-fill regions 113 of the reconstructed wafer 100A. As illustrated in FIG. 14, an intermediate compound layer 125 is formed between the bonding layer 115 and the reconstructed wafer 100A by chemical reactions between the material of the bonding layer 115 and the materials of the reconstructed wafer 100A. In an alternative embodiment, the plasma process 123 is performed to treat (e.g., activate) the upper surfaces of the semiconductor dies 50, the dummy dies 111, and the gap-fill regions 113 (instead of treating the bonding layer 115), and the bonding layer 115 is then bonded to the treated upper surfaces of the semiconductor dies 50, the dummy dies 111, and the gap-fill regions 113 to form the structure of FIG. 14.

Note that in the example of FIG. 14, the intermediate compound layer 125 comprises different portions, labeled as intermediate compound layers 125A and 125B in FIG. 14, which different portions comprising different compound materials. The different portions (e.g., 125A and 125B) of the intermediate compound layer 125 are formed at different locations between the bonding layer 115 and different regions of the reconstructed wafer 100A formed of different materials. In an example where the bonding layer 115 is formed of AlOₓ, the support substrate 19 and the dummy dies 111 are formed of Si, and the gap-fill regions 113 are formed of SiO_{y}, the intermediate compound layers 125A and 125B comprise AlSiO_{z} and AlSiO_{w}, respectively, where Z≠W. In other words, the atomic percentages of the different atoms in the intermediate compound layers 125A and 125B are different. In another example where the bonding layer 115 is formed of AlOₓ, the support substrate 19 and the dummy dies 111 are formed of Si, and the gap-fill regions 113 are formed of SiN_{y}, the intermediate compound layers 125A and 125B comprise AlSiO_{z} and AlSiN_{w}, respectively.

In some embodiments, the gap-fill regions 113 are formed of a molding material, which may be an organic polymer. In some embodiments, the surface chemistry and reactivity of the molding material are different from those of silicon or a non-organic dielectric material (e.g. SiOₓ or SiNₓ), and therefore, the bonding mechanism between the bonding layer 115 and the molding material would likely be physical rather than chemical in nature. For example, the bonding layer 115 and the molding material of the gap-fill regions 113 may be bonded through physical adhesion, Van der Waals forces, or the like, without chemical reaction between the bonding layer 115 and the molding material. As a result, the intermediate compound layers 125B is not formed. In other words, in some embodiments where the gap-fill regions 113 are formed of a molding material, the intermediate compound layer 125 only includes the intermediate compound layers 125A illustrated in FIG. 14. Stated in another way, the intermediate compound layer 125 only includes the discrete (e.g., separate) portions labeled as 125A in FIG. 14, when the gap-fill regions 113 are formed of a molding material, in some embodiments.

Next, the carrier 101 is de-bonded, the RDS 132 is formed, and the connectors 137 are formed. A singulation process may be performed next to separate the reconstructed wafer 100A into individual semiconductor packages 100A. Details are not repeated here.

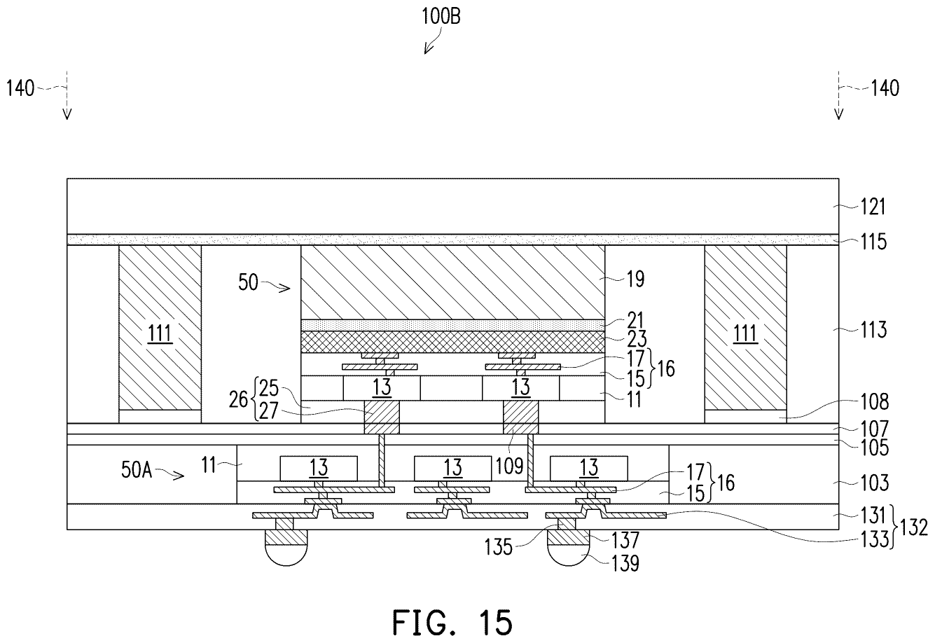

FIG. 15 illustrates a cross-sectional view of a semiconductor structure 100B, in accordance with another embodiment. The semiconductor structure 100B may be formed following the same or similar processing steps for the semiconductor structure 100, but without performing the plasma process 123 to activate the surface of the heat sink 121 (or the bonding layer 115). As a result, the bonding between the bonding layer 115 and the heat sink 121 may be achieved through physical bonding (e.g., Van der Waals forces) instead of chemical bonding (e.g., through chemical bonds formed by chemical reaction). Therefore, no intermediate compound layer 125 is formed in the semiconductor structure 100B. Other details are the same as or similar to those discussed above, thus not repeated.

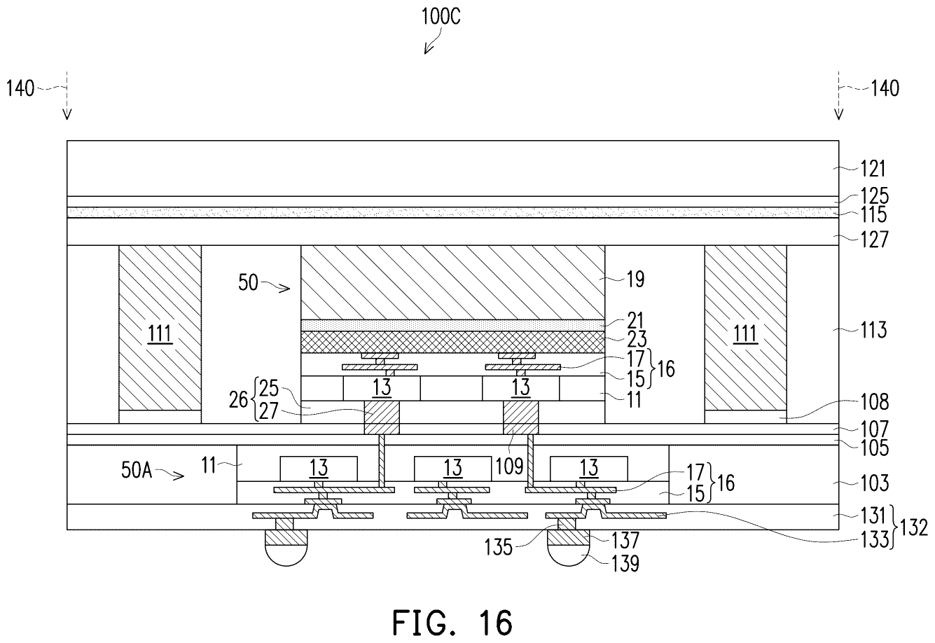

FIG. 16 illustrates a cross-sectional view of a semiconductor structure 100C, in accordance with another embodiment. The semiconductor structure 100C may be formed following the same or similar processing steps for the semiconductor structure 100, but with the formation of another bonding layer 127 (may also be referred to as a bonding film 127) on the reconstructed wafer before forming the bonding layer 115. Note that the bonding layer 115 in the semiconductor package 100 can be considered as replacing both the first bonding layer (e.g., attached to the heat sink 121) and the second bonding layer (e.g., attached to the reconstructed wafer) in the reference package described above, and in contrast, the bonding layer 115 in the semiconductor package 100C can be considered as replacing only the first bonding layer of the reference package.

As illustrated in FIG. 16, after activating the surface of the heat sink 121 (or the bonding layer 115) using the plasma process 123, the heat sink 121 is bonded to the bonding layer 115, and the intermediate compound layer 125 is formed between the heat sink 121 and the bonding layer 115.

In some embodiments, the bonding layer 127 is formed of a suitable dielectric material such as aluminum oxide (e.g., AlOₓ), silicon oxide (e.g., SiOₓ), silicon carbonitride (e.g., SiCN), titanium oxide (e.g., TiO₂), aluminum nitride (e.g., AlN), boron nitride (e.g., BN), silicon oxynitride (e.g., SiON), or silicon oxycarbide (e.g., SiOC), using a suitable formation method such as CVD, ALD, or the like. A thickness of the bonding layer 127 may be between about 5 angstroms and about 2500 angstroms. A thermal conductivity of the bonding layer 115 may be between about 0.5 W/(m·K) and about 20 W/(m·K). In some embodiments, the bonding layers 127 and 115 are formed of a same material.

In some embodiments, the bonding layer 127 is formed to be thicker than the bonding layer 115. For example, the thickness of the bonding layer 127 may be 1.5 times, twice, three times, or more than the thickness of the bonding layer 115. The bonding layer 127 may serve to enhance the planarity of the bonding layer 115 formed subsequently, as discussed hereinafter. In some embodiments, after the gap-filling regions 113 are formed, the planarity of the “coplanar upper surface” of the dummy dies 111, the support substrate 19, and the gap-fill regions 113 may be poor. The poor planarity may be caused by, e.g., the gap-fill regions 113 being formed of a molding material, and the molding material and the material (e.g., silicon) of the dummy dies 111 and the support substrate 19 may respond differently to the planarization process to form the “coplanar upper surface.” If the bonding layer 115, which is ultra-thin (e.g., having a thickness between about 5 angstroms and 2500 angstroms), is formed directly on the gap-fill regions 113, the dummy dies 111, and the support substrate 19, the bonding layer 115 may also have poor planarity, which may result in poor bonding. By forming the bonding layer 127 before the bonding layer 115, the bonding layer 127 can be planarized to achieve a high level of planarity in preparation for the deposition of the bonding layer 115. As a result, the bonding layer 115 formed subsequently has high level of planarity and achieves good adhesion.

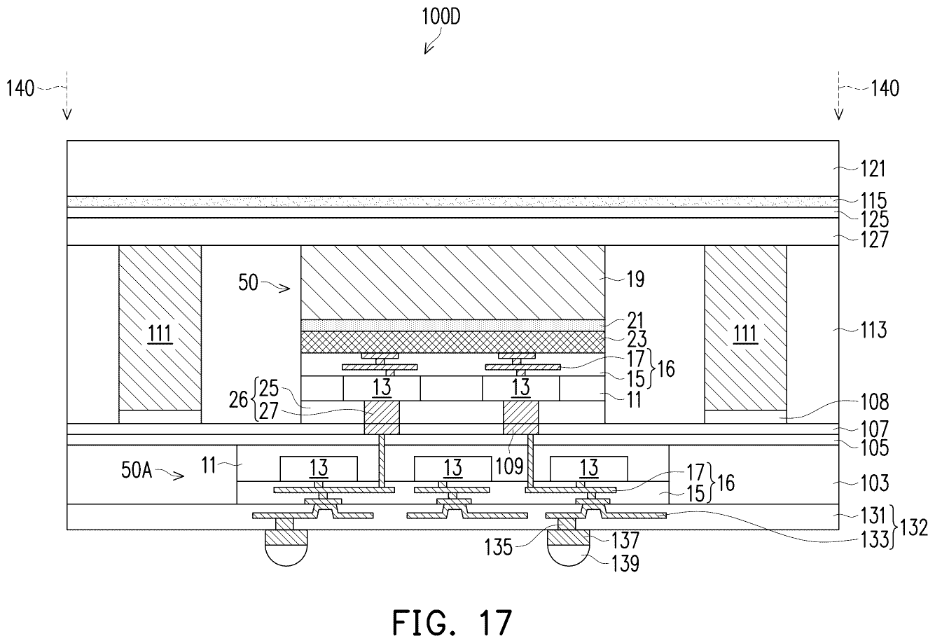

FIG. 17 illustrates a cross-sectional view of a semiconductor structure 100D, in accordance with another embodiment. The semiconductor structure 100D may be formed following the same or similar processing steps for the semiconductor structure 100C, but with the intermediate compound layer 125 formed between the bonding layer 115 and the bonding layer 127. The semiconductor structure 100D may be formed by: forming the bonding layer 127 on the upper surfaces of the support substrate 19, the dummy dies 111, and the gap-fill regions 113; forming the bonding layer 115 on the heat sink 121; activating the surface of the heat sink 121 (or the bonding layer 127) by performing the plasma process 123; and bonding the bonding layers 115 and 127 together. As illustrated in FIG. 17, the intermediate compound layer 125 is formed between the bonding layer 115 and the bonding layer 127.

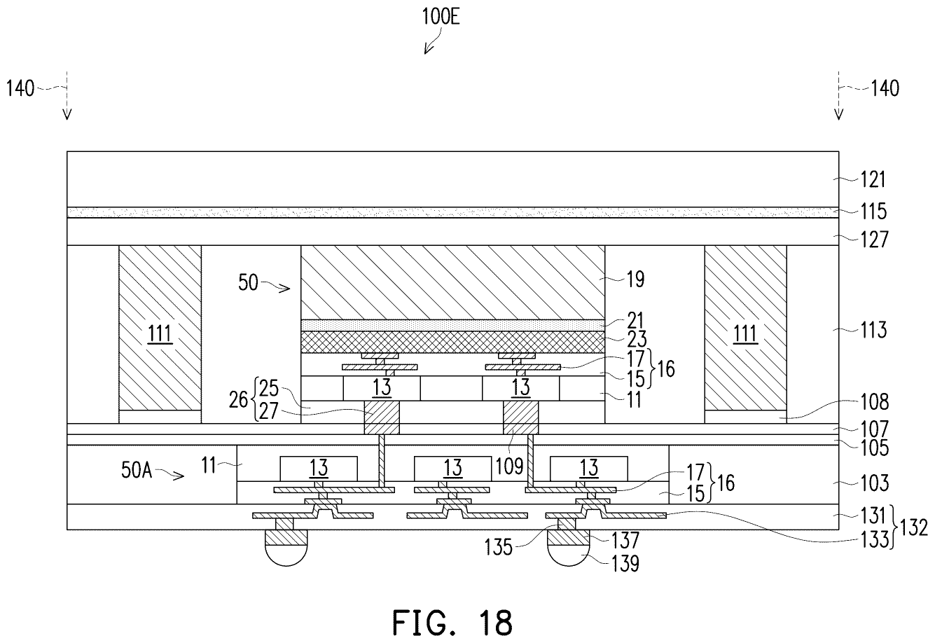

FIG. 18 illustrates a cross-sectional view of a semiconductor structure 100E, in accordance with another embodiment. The semiconductor structure 100E may be formed following the same or similar processing steps for the semiconductor structure 100C (or 100D), but without the intermediate compound layer 125. In some embodiments, the semiconductor structure 100E is formed by omitting the plasma process 123 performed for the semiconductor structure 100C (or 100D). As a result, the intermediate compound layer 125 is not formed in the semiconductor structure 100E.

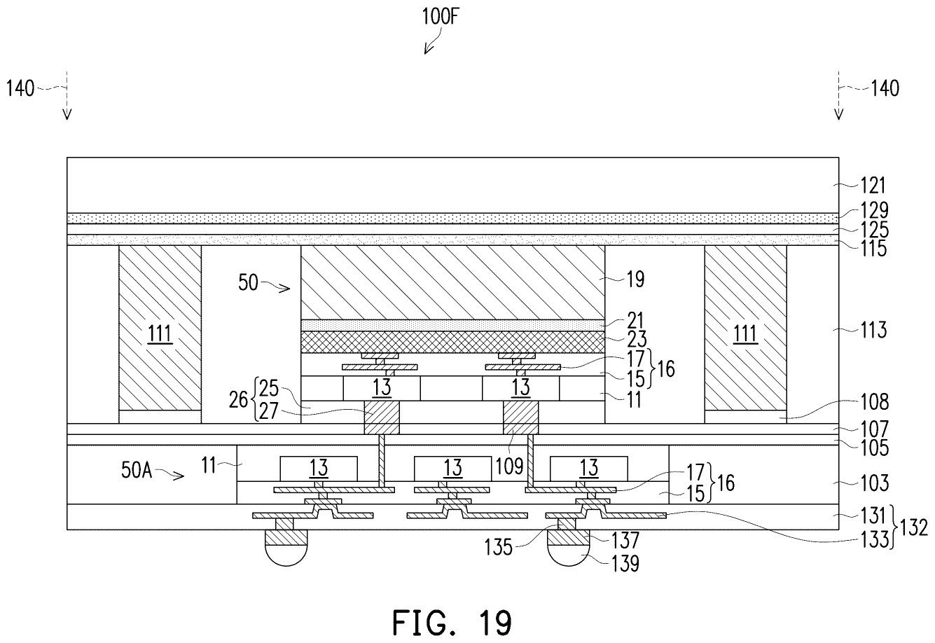

FIG. 19 illustrates a cross-sectional view of a semiconductor structure 100F, in accordance with another embodiment. The semiconductor structure 100F may be formed following the same or similar processing steps for the semiconductor structure 100, but with a bonding layer 129 formed on the heat sink 121 and with the intermediate compound layer 125 formed between the bonding layers 129 and 115. In some embodiments, to form the semiconductor structure 100F, the bonding layer 129 is formed on the surface of the heat sink 121, and the bonding layer 115 is formed on the upper surfaces of the dummy dies 111, the support substrate 19, and the gap-filling regions 113. The bonding layer 129 is formed of a same material with a same thickness as the bonding layer 115, in some embodiments. Next, the plasma process 123 is performed to treat (e.g., activate) the exterior surface of the bonding layer 129 (or the bonding layer 115). Next, the bonding layers 129 is bonded to the bonding layer 115, and the intermediate compound layer 125 is formed between the bonding layers 115 and 129.

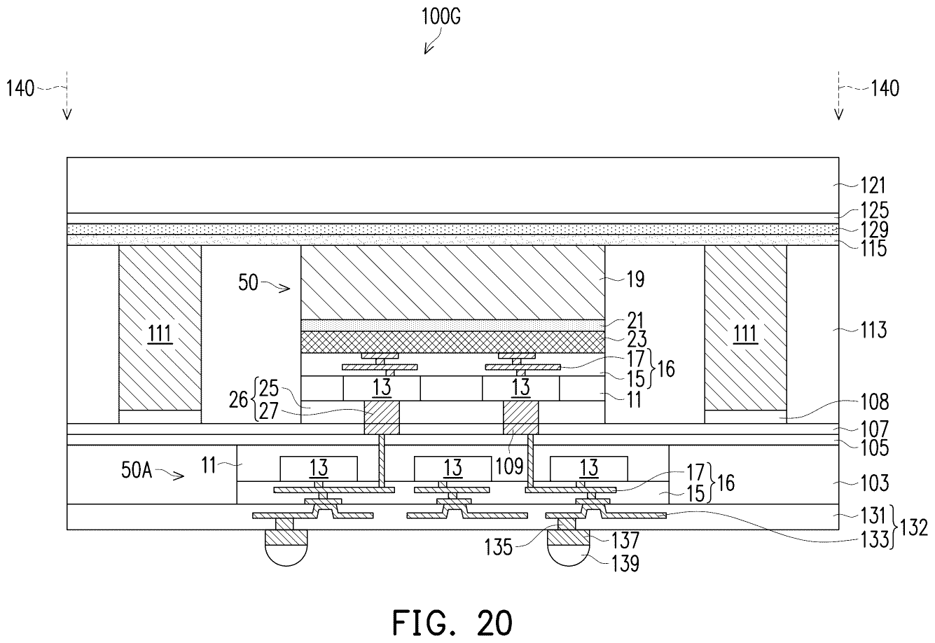

FIG. 20 illustrates a cross-sectional view of a semiconductor structure 100G, in accordance with another embodiment. The semiconductor structure 100G may be formed following the same or similar processing steps for the semiconductor structure 100F, but with the bonding layer 129 formed on the bonding layer 115 before the bonding of the heat sink 121. Next, the plasma process 123 is performed to treat (e.g., activate) the surface of the heat sink 121 or the surface of the bonding layer 129. Next, the heat sink 121 is bonded to the bonding layer 129, and the intermediate compound layer 125 is formed between the heat sink 121 and the bonding layer 129. Although not shown, another alternative embodiment is to form the bonding layers 129 and 115 on the heat sink 121 sequentially, performing the plasma process 123 to activate the exterior surface of the bonding layer 115, or to activate the upper surfaces of the dummy dies 111, the support substrate 19, and the gap-fill regions 113, then bonding the bonding layer 115 to the upper surfaces the dummy dies 111, the support substrate 19, and the gap-fill regions 113. In this alternative embodiment, the intermediate compound layer 125 is formed between the bonding layer 115 and the upper surfaces of the dummy dies 111, the support substrate 19, and the gap-fill regions 113, same as or similar to the intermediate compound layer 125 illustrated in FIG. 14.

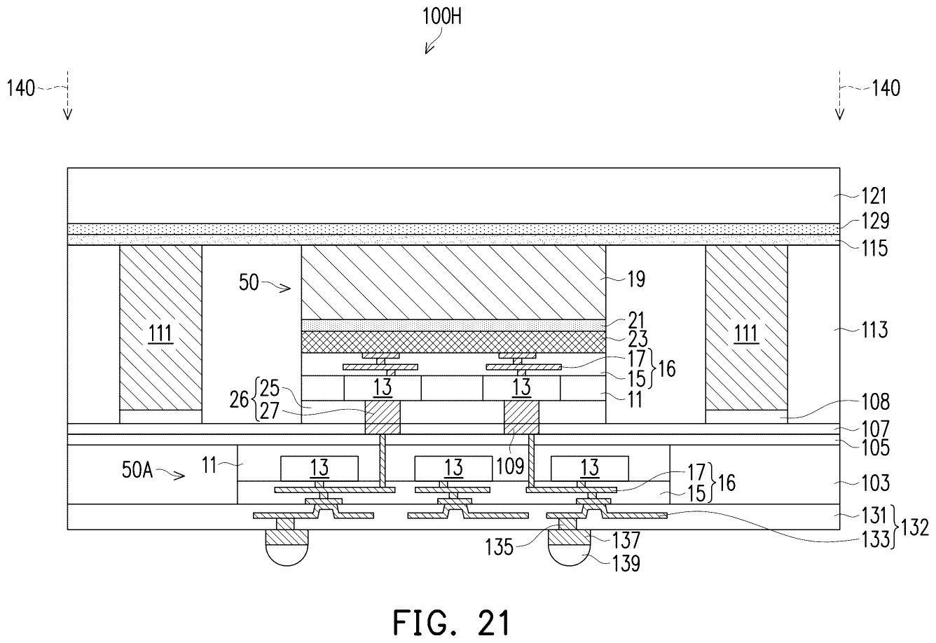

FIG. 21 illustrates a cross-sectional view of a semiconductor structure 100H, in accordance with another embodiment. The semiconductor structure 100H may be formed following the same or similar processing steps for the semiconductor structure 100F (or 100G), but without the intermediate compound layer 125. In some embodiments, the semiconductor structure 100H is formed by omitting the plasma process 123 performed for the semiconductor structure 100F (or 100G). As a result, the intermediate compound layer 125 is not formed in the semiconductor structure 100E.

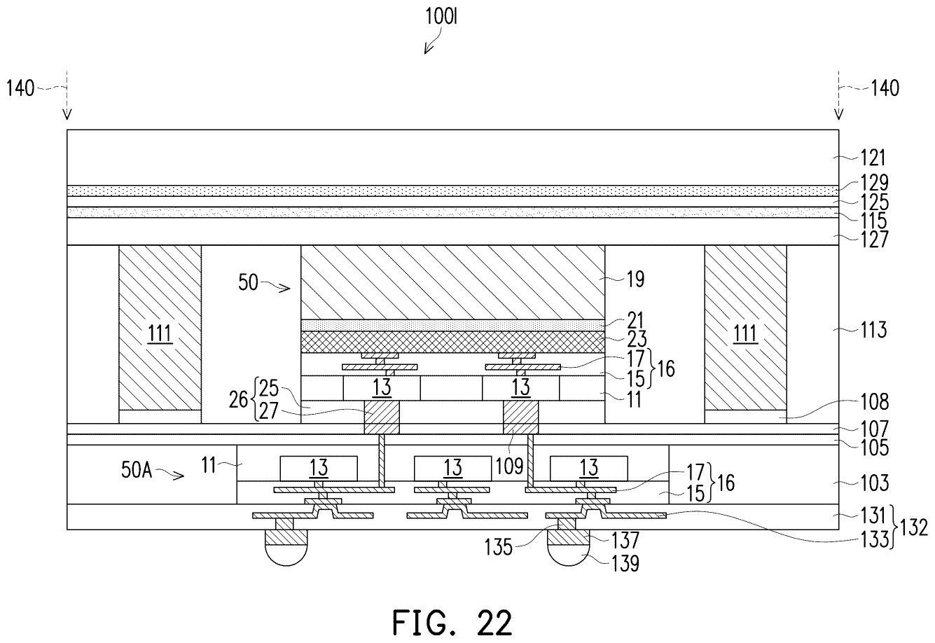

FIG. 22 illustrates a cross-sectional view of a semiconductor structure 100I, in accordance with another embodiment. The semiconductor structure 100I may be formed following the same or similar processing steps for the semiconductor structure 100F, but with the bonding layer 127 formed on the upper surfaces of the dummy dies 111, the support substrate 19, and the gap-fill regions 113 before the bonding layer 115 is formed. The bonding layer 127 may serve to improve the planarity of the bonding layer 115, as discussed above, and may have a thickness that is larger (e.g., 1.5 times, twice, three times, or more) than the thickness of the bonding layer 115 or 129. The intermediate compound layer 125 is formed between the bonding layers 129 and 115.

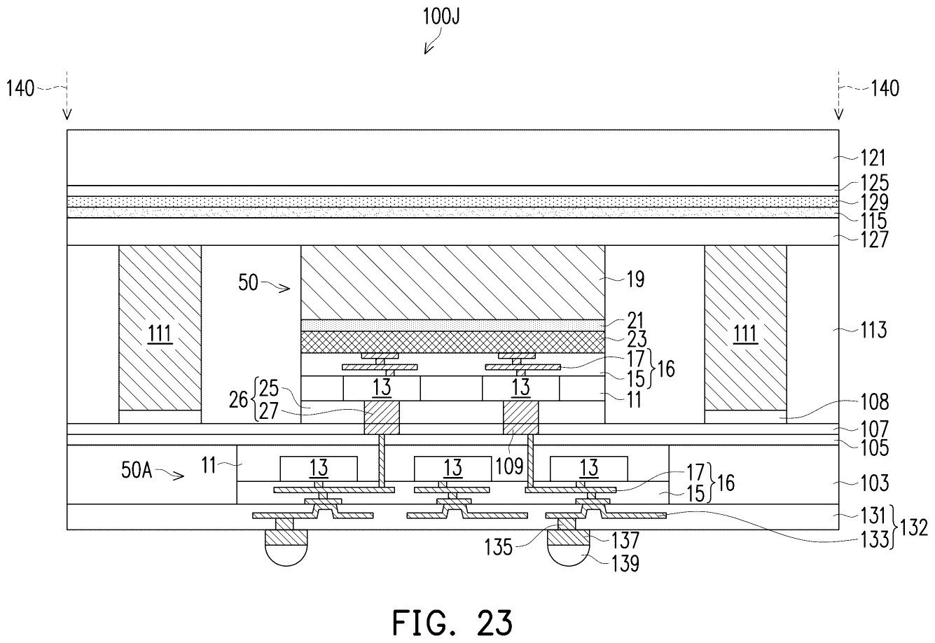

FIG. 23 illustrates a cross-sectional view of a semiconductor structure 100J, in accordance with another embodiment. The semiconductor structure 100J may be formed following the same or similar processing steps for the semiconductor structure 100G, but with the bonding layer 127 formed on the upper surfaces of the dummy dies 111, the support substrate 19, and the gap-fill regions 113 before the bonding layer 115 is formed. The bonding layer 127 may serve to improve the planarity of the bonding layer 115, as discussed above, and may have a thickness that is larger (e.g., 1.5 times, twice, three times, or more) than the thickness of the bonding layer 115 or 129. The intermediate compound layer 125 is formed between the heat sink 121 and the bonding layer 129.

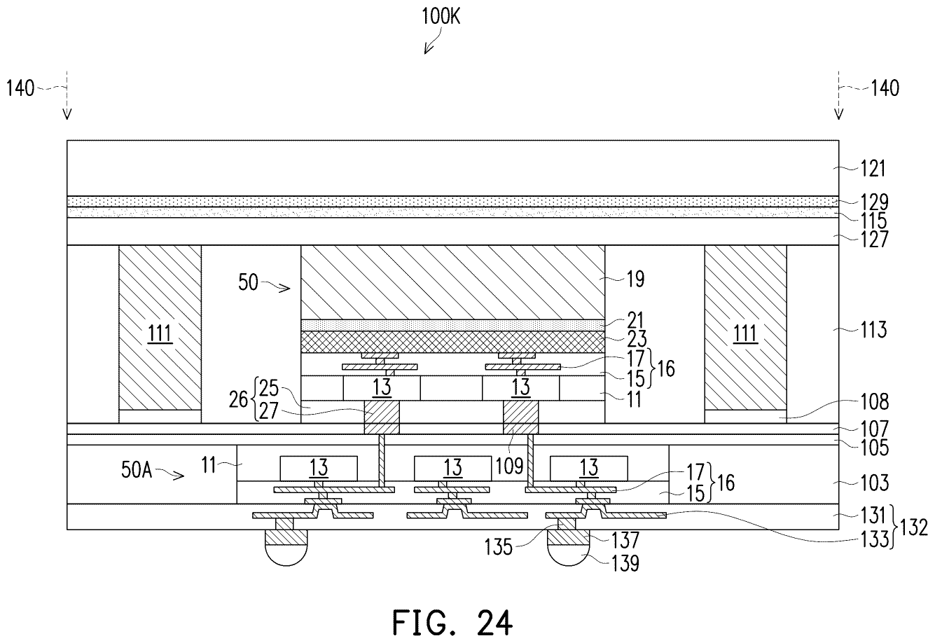

FIG. 24 illustrates a cross-sectional view of a semiconductor structure 100K, in accordance with yet another embodiment. The semiconductor structure 100K may be formed following the same or similar processing steps for the semiconductor structure 100H, but with the bonding layer 127 formed on the upper surfaces of the dummy dies 111, the support substrate 19, and the gap-fill regions 113 before the bonding layer 115 is formed. The bonding layer 127 may serve to improve the planarity of the bonding layer 115, as discussed above, and may have a thickness that is larger (e.g., 1.5 times, twice, three times, or more) than the thickness of the bonding layer 115 or 129. The plasma process 123 is omitted, and therefore, no intermediate compound layer 125 is formed in the semiconductor structure 100K.

Variations and modifications to the disclosed embodiments are possible, and are fully intended to be included within the scope of the present disclosure. For example, in FIG. 2, the bonding between the bonding layers 21 and 23 of the semiconductor die 50 is illustrated as a direct dielectric-to-dielectric bonding as a non-limiting example, in order to illustrate the attaching of the support substrate 19 to the interconnect structure 16. By forming the bonding layer 21 using the same material with the same thickness as the bonding layer 115, and by treating (e.g., considering) the bonding layer 21 as if it is the ultra-thin bonding layer 115, the attaching of the support substrate 19 to the interconnect structure 16 may be achieved by any of the disclosed bonding schemes herein. For example, the plasma process 123 may be performed to activate at least one of the bonding surfaces, and as a result, the intermediate compound layer 125 is formed at the bonding interface, e.g., somewhere between the support substrate 19 and the interconnect structure 16 of the semiconductor die 50, depending on which surface is treated by the plasma process 123. As another example, only the bonding layer 21 is used for bonding, and the bonding layer 23 may be omitted. As yet another example, two ultra-thin bonding layers 21 may be used at the bonding interface, with or without the bonding layer 127.

The disclosed embodiments achieve various advantages. For example, the disclosed semiconductor structures use the ultra-thin bonding layer (e.g., 115) at a bonding interface to replace either one or both of the bonding layers used in a reference package without the disclosed bonding scheme/structure. The disclosed bonding layer has a thickness that is between about 1/10 and about 1/100 of the thickness of the bonding layers used in the reference package, therefore greatly improving heat dissipation efficiency and reducing thermal resistance. A plasma process is performed to activate at least one of the two surfaces to be bonded together before the bonding. As a result, an intermediate compound layer is formed at the bonding interface by chemical bonds formed by chemical reaction between the materials of the bonding surfaces. The intermediate compound layer provides enhanced adhesion. The ultra-thin bonding layer also has improved planarity, due to the deposition method (e.g., ALD) used and/or an underlying bonding layer (e.g., 127). The enhanced adhesion, together with the improved planarity, achieves strong bonding at the bonding interface with little or no void regions (e.g., air bubbles), which further improves the heat dissipation efficiency. The improved heat dissipation efficiency allows inexpensive materials, such as silicon, to be used as the material for the heat sink and/or dummy dies used in the semiconductor package, which reduces production cost. The ultra-thin bonding layer also reduces the height of the semiconductor structure formed.

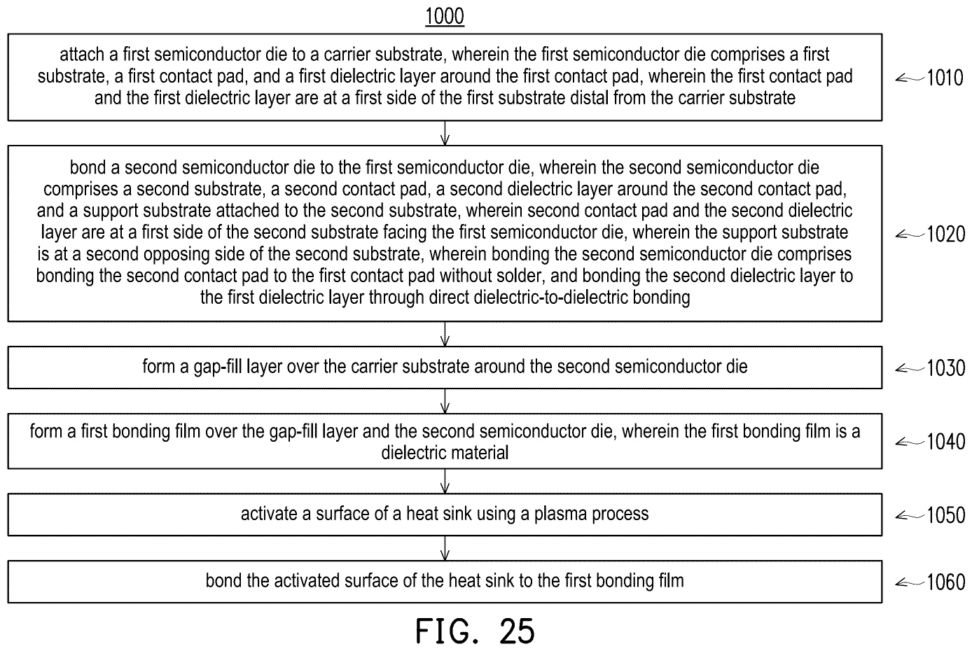

FIG. 25 illustrates a flow chart of a method of forming a semiconductor device, in some embodiments. It should be understood that the embodiment method shown in FIG. 25 is merely an example of many possible embodiment methods. One of ordinary skill in the art would recognize many variations, alternatives, and modifications. For example, various steps as illustrated in FIG. 25 may be added, removed, replaced, rearranged and repeated.

Referring to FIG. 25, at block 1010, a first semiconductor die is attached to a carrier substrate, wherein the first semiconductor die comprises a first substrate, a first contact pad, and a first dielectric layer around the first contact pad, wherein the first contact pad and the first dielectric layer are at a first side of the first substrate distal from the carrier substrate. At block 1020, a second semiconductor die is bonded to the first semiconductor die, wherein the second semiconductor die comprises a second substrate, a second contact pad, a second dielectric layer around the second contact pad, and a support substrate attached to the second substrate, wherein second contact pad and the second dielectric layer are at a first side of the second substrate facing the first semiconductor die, wherein the support substrate is at a second opposing side of the second substrate, wherein bonding the second semiconductor die comprises bonding the second contact pad to the first contact pad without solder, and bonding the second dielectric layer to the first dielectric layer through direct dielectric-to-dielectric bonding. At block 1030, a gap-fill layer is formed over the carrier substrate around the second semiconductor die. At block 1040, a first bonding film is formed over the gap-fill layer and the second semiconductor die, wherein the first bonding film is a dielectric material. At block 1050, a surface of a heat sink is activated using a plasma process. At block 1060, the activated surface of the heat sink is bonded to the first bonding film.

In accordance with an embodiment, a method of forming a semiconductor structure includes: attaching a first semiconductor die to a carrier substrate, wherein the first semiconductor die comprises a first substrate, a first contact pad, and a first dielectric layer around the first contact pad, wherein the first contact pad and the first dielectric layer are at a first side of the first substrate distal from the carrier substrate; bonding a second semiconductor die to the first semiconductor die, wherein the second semiconductor die comprises a second substrate, a second contact pad, a second dielectric layer around the second contact pad, and a support substrate attached to the second substrate, wherein second contact pad and the second dielectric layer are at a first side of the second substrate facing the first semiconductor die, wherein the support substrate is at a second opposing side of the second substrate, wherein bonding the second semiconductor die comprises bonding the second contact pad to the first contact pad without solder, and bonding the second dielectric layer to the first dielectric layer through direct dielectric-to-dielectric bonding; forming a gap-fill layer over the carrier substrate around the second semiconductor die; forming a first bonding film over the gap-fill layer and the second semiconductor die, wherein the first bonding film is a dielectric material; activating a surface of a heat sink using a plasma process; and bonding the activated surface of the heat sink to the first bonding film. In an embodiment, bonding the activated surface of the heat sink comprises placing the activated surface of the heat sink in direct contact with the first bonding film, wherein after bonding the activated surface of the heat sink, an intermediate compound layer is formed between the heat sink and the first bonding film. In an embodiment, the intermediate compound layer comprises a compound material formed by chemical reaction between a first material at the activated surface of the heat sink and a second material of the first bonding film. In an embodiment, the heat sink is a bulk silicon material. In an embodiment, the first bonding film is aluminum oxide, and the compound material is aluminum silicon oxide. In an embodiment, the heat sink is a bulk silicon material, and the first bonding film is aluminum oxide, silicon oxide, silicon carbonitride, titanium oxide, aluminum nitride, boron nitride, silicon oxynitride, or silicon oxycarbide. In an embodiment, a first thickness of the first bonding film is between about ten times and about 100 times a second thickness of the intermediate compound layer. In an embodiment, a thermal conductivity of the first bonding film is between about 0.5 watts per meter per Kelvin (W/(m·K)) and about 20 W/(m·K). In an embodiment, the method further comprises, before forming the first bonding film, forming a second bonding film over the gap-fill layer and the second semiconductor die, wherein after forming the first bonding film, the second bonding film is disposed between the first bonding film and the gap-fill layer. In an embodiment, a third thickness of the second bonding film is larger than the first thickness of the first bonding film. In an embodiment, the first bonding film and the second bonding film are formed of a same material.

In accordance with an embodiment, a method of forming a semiconductor structure includes: attaching a bottom die to a carrier substrate, wherein the bottom die comprises a first semiconductor substrate, an interconnect structure at a first side of the first semiconductor substrate, and a through substrate via (TSV) extending from a conductive feature of the interconnect structure into the first semiconductor substrate, wherein after attaching the bottom die, the interconnect structure is interposed between the carrier substrate and the first semiconductor substrate of the bottom die; forming a first gap-fill layer on the carrier substrate around the bottom die; after forming the first molding material, thinning the first semiconductor substrate from a second side of the first semiconductor substrate distal from the carrier substrate, wherein after the thinning, the TSV protrudes above the second side of the first semiconductor substrate; after the thinning, forming a first dielectric layer over the first gap-fill layer and the bottom die; forming a first contact pad in the first dielectric layer and electrically coupled to the TSV, wherein the TSV provides electrical connection from the conductive feature to the first contact pad through the first semiconductor substrate; bonding a second contact pad of a top die to the first contact pad; after bonding the second contact pad, forming a second gap-fill layer over the first dielectric layer around the top die; forming a bonding layer over the second gap-fill layer and the top die, wherein the bonding layer comprises a dielectric material; treating a surface of a heat sink by performing a plasma process; and after the treating, bonding the surface of the heat sink to the bonding layer. In an embodiment, after the thinning, an upper portion of the TSV protrudes above the second side of the first semiconductor substrate, wherein the method further comprises, after the thinning and before forming the first dielectric layer, forming a second dielectric layer on the first gap-fill layer and the bottom die, wherein the second dielectric layer contacts and extends along sidewalls of the upper portion of the TSV, wherein the second dielectric layer and the TSV have a level upper surface distal from the carrier substrate, wherein the first dielectric layer is formed on the second dielectric layer. In an embodiment, after bonding the surface of the heat sink, an intermediate compound layer is formed between the heat sink and the bonding layer, wherein the intermediate compound layer comprises a compound material formed by chemical reaction between a first material of the heat sink and a second material of the bonding layer. In an embodiment, the second contact pad of the top die is bonded to the first contact pad without using solder, wherein a second dielectric layer of the top die is bonded to the first dielectric layer through direct dielectric-to-dielectric bonding. In an embodiment, the method further comprises, before forming the second gap-fill layer, attaching a dummy die to the first dielectric layer using a glue layer interposed between the dummy die and the first dielectric layer. In an embodiment, the top die comprises a second semiconductor substrate, the second contact pad at a first side of the second semiconductor substrate facing the bottom die, a support substrate at a second opposing side of the second semiconductor substrate, and another bonding layer between the support substrate and the second semiconductor substrate, wherein the bonding layer and the another bonding layer are formed of a same material, wherein the dummy die, the support substrate, and the second gap-fill layer have a level upper surface distal from the bottom die.

In accordance with an embodiment, a semiconductor structure includes: a bottom die; a first gap-fill layer around the bottom die; a top die bonded to the bottom die, wherein a first contact pad of the bottom die is bonded to a second contact pad of the top die through direct metal-to-metal bonding, and a first dielectric layer of the bottom die is bonded to a second dielectric layer of the top die through direct dielectric-to-dielectric bonding; a second gap-fill layer over the first gap-fill layer and around the top die; a bonding layer over the second gap-fill layer and the top die; a heat sink bonded to the bonding layer; and an intermediate compound layer interposed between the bonding layer and the heat sink, wherein the intermediate compound layer comprises a compound material, wherein the compound material comprises chemical bonds between a first material of the heat sink and a second material of the bonding layer. In an embodiment, the heat sink is a bulk silicon material, wherein the bonding layer comprises aluminum oxide, silicon oxide, silicon carbonitride, titanium oxide, aluminum nitride, boron nitride, silicon oxynitride, or silicon oxycarbide. In an embodiment, a thickness of the bonding layer is between about 5 angstroms and about 2500 angstroms, and a thermal conductivity of the bonding layer is between about 0.5 watts per meter per Kelvin (W/(m·K)) and about 20 W/(m·K).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, the method comprising:
attaching a first semiconductor die to a carrier substrate, wherein the first semiconductor die comprises a first substrate, a first contact pad, and a first dielectric layer around the first contact pad, wherein the first contact pad and the first dielectric layer are at a first side of the first substrate distal from the carrier substrate;
bonding a second semiconductor die to the first semiconductor die, wherein the second semiconductor die comprises a second substrate, a second contact pad, a second dielectric layer around the second contact pad, and a support substrate attached to the second substrate, wherein second contact pad and the second dielectric layer are at a first side of the second substrate facing the first semiconductor die, wherein the support substrate is at a second opposing side of the second substrate, wherein bonding the second semiconductor die comprises bonding the second contact pad to the first contact pad without solder, and bonding the second dielectric layer to the first dielectric layer through direct dielectric-to-dielectric bonding;
forming a gap-fill layer over the carrier substrate around the second semiconductor die;
forming a first bonding film over the gap-fill layer and the second semiconductor die, wherein the first bonding film is a dielectric material;
activating a surface of a heat sink using a plasma process; and
bonding the activated surface of the heat sink to the first bonding film.

2. The method of claim 1, wherein bonding the activated surface of the heat sink comprises placing the activated surface of the heat sink in direct contact with the first bonding film, wherein after bonding the activated surface of the heat sink, an intermediate compound layer is formed between the heat sink and the first bonding film.

3. The method of claim 2, wherein the intermediate compound layer comprises a compound material formed by chemical reaction between a first material at the activated surface of the heat sink and a second material of the first bonding film.

4. The method of claim 3, wherein the heat sink is a bulk silicon material.

5. The method of claim 4, wherein the first bonding film is aluminum oxide, and the compound material is aluminum silicon oxide.

6. The method of claim 3, wherein the heat sink is a bulk silicon material, and the first bonding film is aluminum oxide, silicon oxide, silicon carbonitride, titanium oxide, aluminum nitride, boron nitride, silicon oxynitride, or silicon oxycarbide.

7. The method of claim 3, wherein a first thickness of the first bonding film is between about ten times and about 100 times a second thickness of the intermediate compound layer.

8. The method of claim 7, wherein a thermal conductivity of the first bonding film is between about 0.5 watts per meter per Kelvin (W/(m·K)) and about 20 W/(m·K).

9. The method of claim 7, further comprising, before forming the first bonding film, forming a second bonding film over the gap-fill layer and the second semiconductor die, wherein after forming the first bonding film, the second bonding film is disposed between the first bonding film and the gap-fill layer.

10. The method of claim 9, wherein a third thickness of the second bonding film is larger than the first thickness of the first bonding film.

11. The method of claim 10, wherein the first bonding film and the second bonding film are formed of a same material.

12. A method of forming a semiconductor structure, the method comprising:
attaching a bottom die to a carrier substrate, wherein the bottom die comprises a first semiconductor substrate, an interconnect structure at a first side of the first semiconductor substrate, and a through substrate via (TSV) extending from a conductive feature of the interconnect structure into the first semiconductor substrate, wherein after attaching the bottom die, the interconnect structure is interposed between the carrier substrate and the first semiconductor substrate of the bottom die;
forming a first gap-fill layer on the carrier substrate around the bottom die;
after forming the first molding material, thinning the first semiconductor substrate from a second side of the first semiconductor substrate distal from the carrier substrate, wherein after the thinning, the TSV protrudes above the second side of the first semiconductor substrate;
after the thinning, forming a first dielectric layer over the first gap-fill layer and the bottom die;
forming a first contact pad in the first dielectric layer and electrically coupled to the TSV, wherein the TSV provides electrical connection from the conductive feature to the first contact pad through the first semiconductor substrate;
bonding a second contact pad of a top die to the first contact pad;
after bonding the second contact pad, forming a second gap-fill layer over the first dielectric layer around the top die;
forming a bonding layer over the second gap-fill layer and the top die, wherein the bonding layer comprises a dielectric material;
treating a surface of a heat sink by performing a plasma process; and
after the treating, bonding the surface of the heat sink to the bonding layer.

13. The method of claim 12, wherein after the thinning, an upper portion of the TSV protrudes above the second side of the first semiconductor substrate, wherein the method further comprises, after the thinning and before forming the first dielectric layer, forming a second dielectric layer on the first gap-fill layer and the bottom die, wherein the second dielectric layer contacts and extends along sidewalls of the upper portion of the TSV, wherein the second dielectric layer and the TSV have a level upper surface distal from the carrier substrate, wherein the first dielectric layer is formed on the second dielectric layer.

14. The method of claim 12, wherein after bonding the surface of the heat sink, an intermediate compound layer is formed between the heat sink and the bonding layer, wherein the intermediate compound layer comprises a compound material formed by chemical reaction between a first material of the heat sink and a second material of the bonding layer.

15. The method of claim 12, wherein the second contact pad of the top die is bonded to the first contact pad without using solder, wherein a second dielectric layer of the top die is bonded to the first dielectric layer through direct dielectric-to-dielectric bonding.

16. The method of claim 15, wherein the method further comprises, before forming the second gap-fill layer, attaching a dummy die to the first dielectric layer using a glue layer interposed between the dummy die and the first dielectric layer.

17. The method of claim 16, wherein the top die comprises a second semiconductor substrate, the second contact pad at a first side of the second semiconductor substrate facing the bottom die, a support substrate at a second opposing side of the second semiconductor substrate, and another bonding layer between the support substrate and the second semiconductor substrate, wherein the bonding layer and the another bonding layer are formed of a same material, wherein the dummy die, the support substrate, and the second gap-fill layer have a level upper surface distal from the bottom die.

18. A semiconductor structure comprising:
a bottom die;
a first gap-fill layer around the bottom die;
a top die bonded to the bottom die, wherein a first contact pad of the bottom die is bonded to a second contact pad of the top die through direct metal-to-metal bonding, and a first dielectric layer of the bottom die is bonded to a second dielectric layer of the top die through direct dielectric-to-dielectric bonding;
a second gap-fill layer over the first gap-fill layer and around the top die;
a bonding layer over the second gap-fill layer and the top die;
a heat sink bonded to the bonding layer; and
an intermediate compound layer interposed between the bonding layer and the heat sink, wherein the intermediate compound layer comprises a compound material, wherein the compound material comprises chemical bonds between a first material of the heat sink and a second material of the bonding layer.

19. The semiconductor structure of claim 18, wherein the heat sink is a bulk silicon material, wherein the bonding layer comprises aluminum oxide, silicon oxide, silicon carbonitride, titanium oxide, aluminum nitride, boron nitride, silicon oxynitride, or silicon oxycarbide.

20. The semiconductor structure of claim 19, wherein a thickness of the bonding layer is between about 5 angstroms and about 2500 angstroms, and a thermal conductivity of the bonding layer is between about 0.5 watts per meter per Kelvin (W/(m·K)) and about 20 W/(m·K).
